(19) United States
(12) Patent Application Publication
(10) Pub. No.: US 2024/0321367 A1
(43) Pub. Date: Sep. 26, 2024

(54) SEMICONDUCTOR MEMORY DEVICE

(71) Applicant: Kioxia Corporation, Tokyo (JP)

(72) Inventor: Yoshikazu HARADA, Kawasaki (JP)

(73) Assignee: Kioxia Corporation, Tokyo (JP)

(21) Appl. No.: 18/599,848

(22) Filed: Mar. 8, 2024

(30) Foreign Application Priority Data
Mar. 24, 2023 (JP) 2023-048395

(51) Int. Cl. G11C 16/34; G11C 16/16

(52) U.S. Cl. CPC G11C 16/3445; G11C 16/16; G11C 16/3404

(57) ABSTRACT

According to one embodiment, a semiconductor memory device includes a memory cell including a transistor, an interconnect, and a first circuit. The first circuit performs an erase operation including an erase voltage applying operation of applying an erase voltage between a gate of the transistor and a channel of the transistor via the interconnect, and an erase verify operation of determining a threshold voltage of the memory cell. The first circuit performs a first suspension processing of suspending the erase operation upon receiving a first command during the erase operation. The first circuit performs the erase voltage applying operation or the erase verify operation at the time of resuming the erase operation suspended by the first suspension processing, based on a voltage value of the interconnect at the time of receiving the first command.

### CROSS-REFERENCE TO RELATED APPLICATIONS

This application is based upon and claims the benefit of priority from Japanese Patent Application No. 2023-048395, filed Mar. 24, 2023, the entire contents of which are incorporated herein by reference.

### FIELD

Embodiments described herein relate generally to a semiconductor memory device.

### BACKGROUND

A NAND flash memory is known as a semiconductor memory device.

### BRIEF DESCRIPTION OF THE DRAWINGS

FIG. 1 is a block diagram illustrating an example of a memory system including a semiconductor memory device according to a first embodiment.

FIG. 2 is a block diagram illustrating an example of a configuration of the semiconductor memory device according to the first embodiment.

FIG. 3 is a circuit diagram of a memory cell array in the semiconductor memory device according to the first embodiment.

FIG. 4 is a cross-sectional view illustrating an example of a cross-sectional structure of the memory cell array in the semiconductor memory device according to the first embodiment.

FIG. 5 is a cross-sectional view illustrating an example of a cross-sectional structure of a memory pillar in the semiconductor memory device according to the first embodiment.

FIG. 6 is a diagram describing an example of a sequence of an erase operation of the semiconductor memory device according to the first embodiment.

FIG. 7 is a timing chart illustrating an example of the erase operation of the semiconductor memory device according to the first embodiment.

FIG. 8 is a diagram for describing an example of a relationship between a timing at which an instruction of suspension is received during the erase operation of the semiconductor memory device according to the first embodiment and an operation at the time of resuming the erase operation.

FIG. 9 is a flowchart illustrating an example of the erase operation of the semiconductor memory device according to the first embodiment.

FIG. 10 is a timing chart illustrating an example of the erase operation of the semiconductor memory device according to the first embodiment.

FIG. 11 is a timing chart illustrating another example of the erase operation of the semiconductor memory device according to the first embodiment.

FIG. 12 is a flowchart illustrating an example of the erase operation of a semiconductor memory device according to a second embodiment.

FIG. 13 is a timing chart illustrating an example of the erase operation of the semiconductor memory device according to the second embodiment.

FIG. 14 is a timing chart illustrating another example of the erase operation of the semiconductor memory device according to the second embodiment.

FIG. 15 is a timing chart illustrating another example of the erase operation of the semiconductor memory device according to the second embodiment.

FIG. 16 is a flowchart illustrating an example of the erase operation of a semiconductor memory device according to a third embodiment.

FIG. 17 is a timing chart illustrating an example of the erase operation of the semiconductor memory device according to the third embodiment.

FIG. 18 is a timing chart illustrating another example of the erase operation of the semiconductor memory device according to the third embodiment.

FIG. 19 is a flowchart illustrating an example of the erase operation of a semiconductor memory device according to a first modification of the third embodiment.

FIG. 20 is a timing chart illustrating an example of the erase operation of the semiconductor memory device according to the first modification of the third embodiment.

FIG. 21 is a flowchart illustrating an example of the erase operation of a semiconductor memory device according to a second modification of the third embodiment.

### DETAILED DESCRIPTION

In general, according to one embodiment, a semiconductor memory device includes a memory cell including a transistor, an interconnect, and a first circuit. The first circuit performs an erase operation including an erase voltage applying operation of applying an erase voltage between a gate of the transistor and a channel of the transistor via the interconnect, and an erase verify operation of determining a threshold voltage of the memory cell. The first circuit performs a first suspension processing of suspending the erase operation upon receiving a first command during the erase operation. The first circuit performs the erase voltage applying operation or the erase verify operation at the time of resuming the erase operation suspended by the first suspension processing, based on a voltage value of the interconnect at the time of receiving the first command.

Hereinafter, embodiments will be described with reference to the drawings. In this description, common parts are denoted by common reference numerals throughout the drawings.

Each functional block may not be distinguished as in the following example. For example, some functions may be realized by a functional block different from an exemplary functional block. Furthermore, the exemplary functional block may be divided into finer functional sub-blocks. The embodiments are not limited by which functional block the function is implemented.

In addition, each functional block can be implemented as any one of hardware and computer software or a combination of both.

### 1. First Embodiment

A semiconductor memory device according to a first embodiment will be described. Hereinafter, a NAND flash memory will be described as an example of the semiconductor memory device.

### 1.1 Configuration

### 1.1.1 Configuration of Memory System

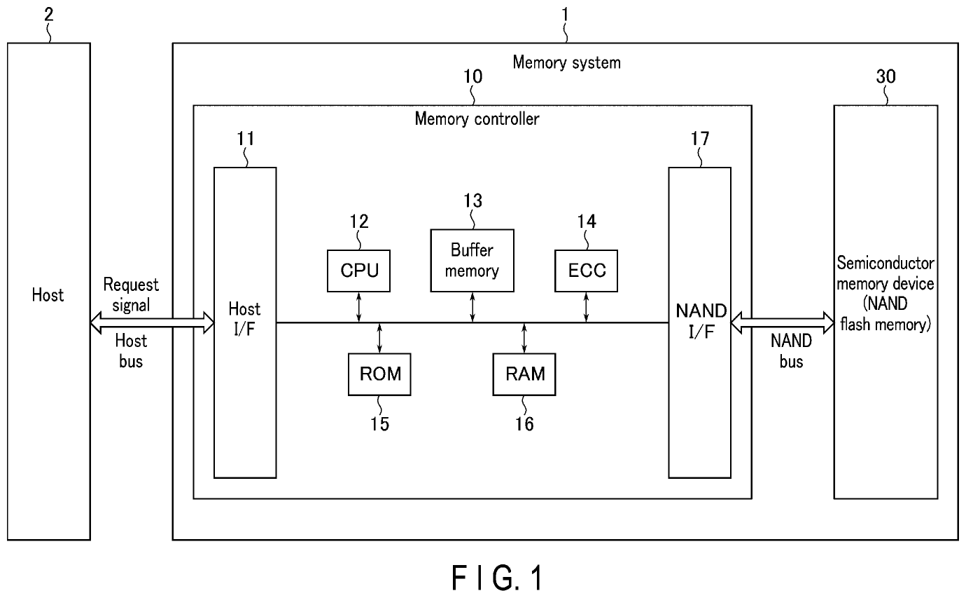

A configuration of a memory system including the semiconductor memory device according to the present embodiment will be described with reference to FIG. 1. FIG. 1 is a block diagram illustrating an example of the memory system including the semiconductor memory device according to the present embodiment.

A memory system 1 is a device that stores data. The memory system 1 is, for example, a solid state drive (SSD), a universal flash storage (UFS) device, a universal serial bus (USB) memory, a multi-media card (MMC), or an SD™ card. The memory system 1 can be connected to a host 2 via a host bus. The memory system 1 performs processing based on a request signal received from the host 2 or a voluntary processing request. The request signal is a request signal for various operations. The various operations are, for example, a write operation, a read operation, and an erase operation. Examples of the voluntary processing request include wear leveling, compaction, and refresh.

The host 2 is a device that controls the memory system 1. The host 2 is, for example, a personal computer, a server system, a mobile device, an in-vehicle device, or a digital camera.

Next, an internal configuration of the memory system 1 will be described.

The memory system 1 includes a memory controller 10 and a semiconductor memory device 30 as functional blocks. The semiconductor memory device 30 is, for example, a non-volatile memory such as a NAND flash memory. Hereinafter, the semiconductor memory device 30 is referred to as a NAND flash memory 30.

The memory controller 10 is a device that controls the NAND flash memory 30. The memory controller 10 is, for example, a system on a chip (SoC). The memory controller 10 is connected to the host 2 via the host bus. The memory controller 10 receives the request signal from the host 2 via the host bus. In addition, the memory controller 10 transmits information to the host 2 via the host bus. The type of the host bus depends on an application applied to the memory system 1. In a case where the memory system 1 is the SSD, for example, an interface of Serial Attached SCSI (SAS), Serial ATA (SATA), or Peripheral Component Interconnect Express (PCIe™) standard is used as the host bus. In a case where the memory system 1 is the UFS device, an M-PHY standard interface is used as the host bus. In a case where the memory system 1 is the USB memory, a USB standard interface is used as the host bus. In a case where the memory system 1 is the MMC, an interface of an embedded Multi Media Card (eMMC) standard is used as the host bus. In a case where the memory system 1 is the SD™ card, an SD™ standard interface is used as the host bus.

The memory controller 10 controls the NAND flash memory 30 via a NAND bus based on the request signal received from the host 2 or the voluntary processing request. The memory controller 10, for example, transmits and receives data to and from the NAND flash memory 30, and transmits a command and an address thereto. The NAND bus transmits and receives a signal according to a NAND interface.

The NAND flash memory 30 is a device that stores data. The NAND flash memory 30 includes a plurality of memory cell transistors. Each of the memory cell transistors stores data in a nonvolatile manner. The NAND flash memory 30 performs the write operation, the read operation, and the erase operation based on the request signal received from the host 2. The write operation is, for example, an operation of writing data in the memory cell transistors. The read operation is, for example, an operation of reading data from the memory cell transistors. The erase operation is, for example, an operation of erasing data written in the memory cell transistors. Therefore, in the write operation, the NAND flash memory 30 stores the data received from the memory controller 10 in the memory cell transistors in a nonvolatile manner. In the read operation, the NAND flash memory 30 outputs data read from the memory cell transistors to the memory controller 10.

Next, an internal configuration of the memory controller 10 will be described.

The memory controller 10 includes, as functional blocks, a host interface (I/F) circuit 11, a processor (central processing unit (CPU)) 12, a buffer memory 13, an error checking and correcting (ECC) circuit 14, a read only memory (ROM) 15, a random access memory (RAM) 16, and a NAND interface (I/F) circuit 17.

The host interface circuit 11 is a circuit that manages communication between the memory controller 10 and the host 2. The host interface circuit 11 is connected to the host 2 via the host bus.

The processor 12 is a control circuit of the memory controller 10. The processor 12 controls the entire operation of the memory controller 10 by executing a program (firmware) stored in the ROM 15. For example, in a case of receiving a request signal of the write operation from the host 2, the processor 12 controls the write operation based on the request signal. The same applies to the read operation and the erase operation.

The buffer memory 13 is a memory that temporarily stores data. The buffer memory 13 is, for example, a static random access memory (SRAM). The buffer memory 13 temporarily stores write data, read data, and the like. The write data is data to be written to the NAND flash memory 30. The read data is data read from the NAND flash memory 30.

The ECC circuit 14 is a circuit that performs data error correction (ECC) processing. Specifically, the ECC circuit 14 generates an error correction code based on the write data during a data write operation. Then, during a data read operation, the ECC circuit 14 detects an error by generating a syndrome based on the error correction code in a predetermined unit, and corrects the detected error.

The ROM 15 is a nonvolatile memory. The ROM 15 is, for example, an electrically erasable programmable read-only memory (EEPROM™). The ROM 15 stores programs such as firmware.

The RAM 16 is a volatile memory. The RAM 16 is, for example, an SRAM. The RAM 16 is used as a work area of the processor 12. The RAM 16 stores firmware for managing the NAND flash memory 30 and various types of management information.

The NAND interface circuit 17 is a circuit that manages communication between the memory controller 10 and the NAND flash memory 30. The NAND interface circuit 17 is connected to the NAND flash memory 30 via the NAND bus. For example, the NAND interface circuit 17 controls transfer of data, commands, addresses, and the like between the memory controller 10 and the NAND flash memory 30.

### 1.1.2 Configuration of NAND Flash Memory

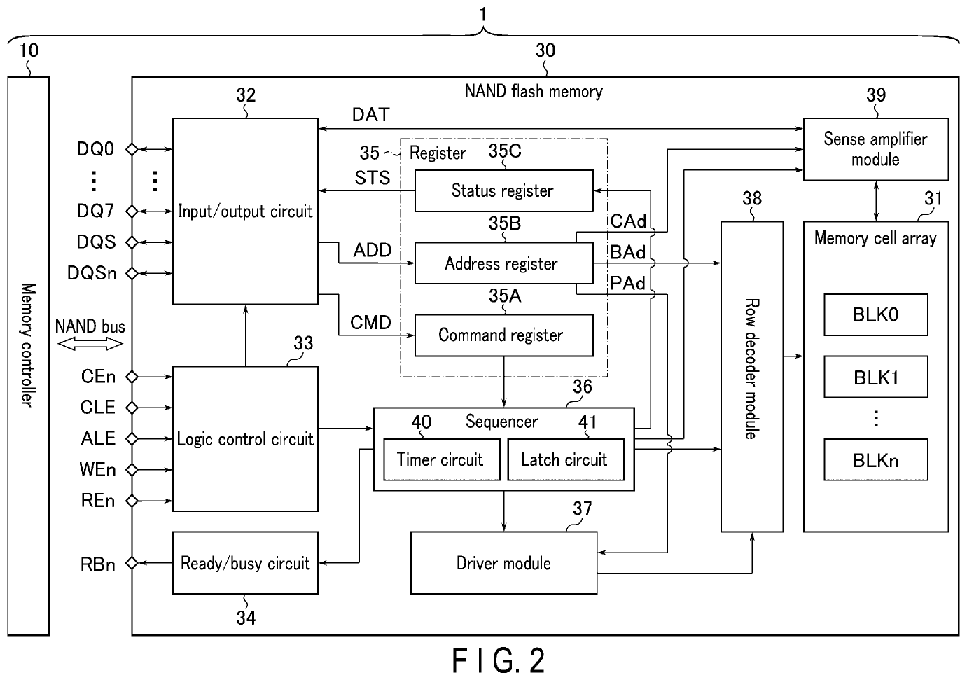

A configuration of the NAND flash memory 30 will be described with reference to FIG. 2. FIG. 2 is a block diagram illustrating an example of the configuration of the NAND flash memory 30. The NAND flash memory 30 includes, as functional blocks, a memory cell array 31, an input/output circuit 32, a logic control circuit 33, a ready/busy circuit 34, a register 35, a sequencer 36, a driver module 37, a row decoder module 38, and a sense amplifier module 39.

The memory cell array 31 includes a plurality of blocks BLK0 to BLKn (n is an integer of 1 or more). Hereinafter, in a case where the blocks BLK0 to BLKn are not distinguished, they are simply referred to as a block BLK. The block BLK is, for example, a set of the memory cell transistors from which data is collectively erased. For example, the block BLK is used as a unit of a data erase operation. A plurality of bit lines and a plurality of word lines are provided in the memory cell array 31. The memory cell transistor is associated with, for example, one bit line and one word line. Details of the memory cell array 31 will be described later.

The input/output circuit 32 is a circuit that transmits and receives signals and information to and from the memory controller 10. The input/output circuit 32 transmits and receives an input/output signal DQ (for example, 8-bit signals DQ0 to DQ7) and a data strobe signal DQS, and a data strobe signal DQSn (an inversion signal of the signal DQS) to and from the memory controller 10. The signal DQ is data transmitted and received between the NAND flash memory 30 and the memory controller 10. The signal DQ includes, for example, a command CMD, an address ADD, status information STS, and data DAT. The signals DQS and DQSn are signals for controlling a transmission/reception timing of the signal DQ. For example, during the data write operation, the signals DQS and DQSn are transmitted from the memory controller 10 to the NAND flash memory 30 together with the signal DQ including the write data. The NAND flash memory 30 receives the signal DQ including write data in synchronization with the signals DQS and DQSn. Further, during the data read operation, the signals DQS and DQSn are transmitted from the NAND flash memory 30 to the memory controller 10 together with the signal DQ including the read data. The memory controller 10 receives the signal DQ including the read data in synchronization with the signals DQS and DQSn. Note that the input/output circuit 32 may receive the signals DQS and DQSn from the memory controller 10 via the logic control circuit 33.

The logic control circuit 33 is a circuit that controls the input/output circuit 32 and the sequencer 36 based on a control signal. The logic control circuit 33 receives, as control signals, a chip enable signal CEn, a command latch enable signal CLE, an address latch enable signal ALE, a write enable signal WEn, and a read enable signal REn from the memory controller 10. The signal CEn is a signal for enabling the NAND flash memory 30. The signal CLE is a signal indicating that the signal DQ received by the NAND flash memory 30 is the command CMD. The signal ALE is a signal indicating that the signal DQ received by the NAND flash memory 30 is the address ADD. The signal WEn is a signal that enables input of the signal DQ to the NAND flash memory 30, for example, in the write operation. The signal REn is a signal that enables output of the signal DQ from the NAND flash memory 30, for example, in the read operation. The NAND flash memory 30 generates the signals DQS and DQSn based on the signal REn. The NAND flash memory 30 outputs the signal DQ to the memory controller 10 based on the generated signals DQS and DQSn.

The ready/busy circuit 34 is a circuit that notifies the memory controller 10 of an operation status of the sequencer 36. The ready/busy circuit 34 transmits a ready/busy signal RBn to the memory controller 10 based on the operation status of the sequencer 36. The signal RBn is a signal indicating whether the NAND flash memory 30 is in a ready state or a busy state. For example, the signal RBn is set to a “High” level (hereinafter, also referred to as a “H level”) in a case where the NAND flash memory 30 is in the ready state. The ready state is a state in which the NAND flash memory 30 can receive a command from the memory controller 10. For example, the signal RBn is set to a “Low” level (hereinafter, also referred to as a “L level”) in a case where the NAND flash memory 30 is in the busy state. The busy state is a state in which the NAND flash memory 30 cannot receive a command from the memory controller 10.

The register 35 is a circuit that temporarily stores information. The register 35 includes a command register 35A, an address register 35B, and a status register 35C.

The command register 35A is a circuit that stores the command CMD included in the signal DQ. The command CMD is received from the input/output circuit 32. The command CMD includes, for example, an order for causing the sequencer 36 to perform the read operation, the write operation, and the erase operation.

The address register 35B is a circuit that stores the address ADD included in the signal DQ. The address ADD is received from the input/output circuit 32. The address ADD includes, for example, a block address BAd, a page address PAd, and a column address CAd. The block address BAd, the page address PAd, and the column address CAd are respectively used, for example, to select the block BLK, the word line, and the bit line.

The status register 35C is, for example, a circuit that temporarily stores the status information STS in the read operation, the write operation, and the erase operation. The status information STS is used to notify the memory controller 10 whether the operation has been normally ended. Therefore, the input/output circuit 32 receives the status information STS from the status register 35C.

The sequencer 36 controls the entire operation of the NAND flash memory 30. For example, the sequencer 36 controls the ready/busy circuit 34, the driver module 37, the row decoder module 38, and the sense amplifier module 39 based on the command CMD stored in the command register 35A, and performs various operations of the NAND flash memory 30.

The sequencer 36 includes a timer circuit 40 and a latch circuit 41. Note that the sequencer 36 may include two or more latch circuits 41.

The timer circuit 40 measures, for example, a time during which an erase voltage VERA is applied in the erase operation.

The latch circuit 41 temporarily stores, for example, information used in the erase operation. The information used in the erase operation includes, for example, application time information Iat, resumption operation information Iar, and erase verify operation information Ivfy.

The driver module 37 is a circuit that generates a voltage used in the read operation, the write operation, and the erase operation. The driver module 37 applies the generated voltage to the selected word line based on the page address PAd stored in the address register 35B.

The row decoder module 38 is a circuit that selects one block BLK in the memory cell array 31 based on the block address BAd stored in the address register 35B.

The sense amplifier module 39 transmits and receives the data DAT in the signal DQ to and from the input/output circuit 32. In the write operation, the sense amplifier module 39 applies a voltage based on write data DAT received from the input/output circuit 32 to the bit line. Further, in the read operation, the sense amplifier module 39 determines the data stored in the memory cell transistor based on the voltage of the bit line. The sense amplifier module 39 transfers a determination result to the input/output circuit 32 as read data DAT.

### 1.1.3 Circuit Configuration of Memory Cell Array

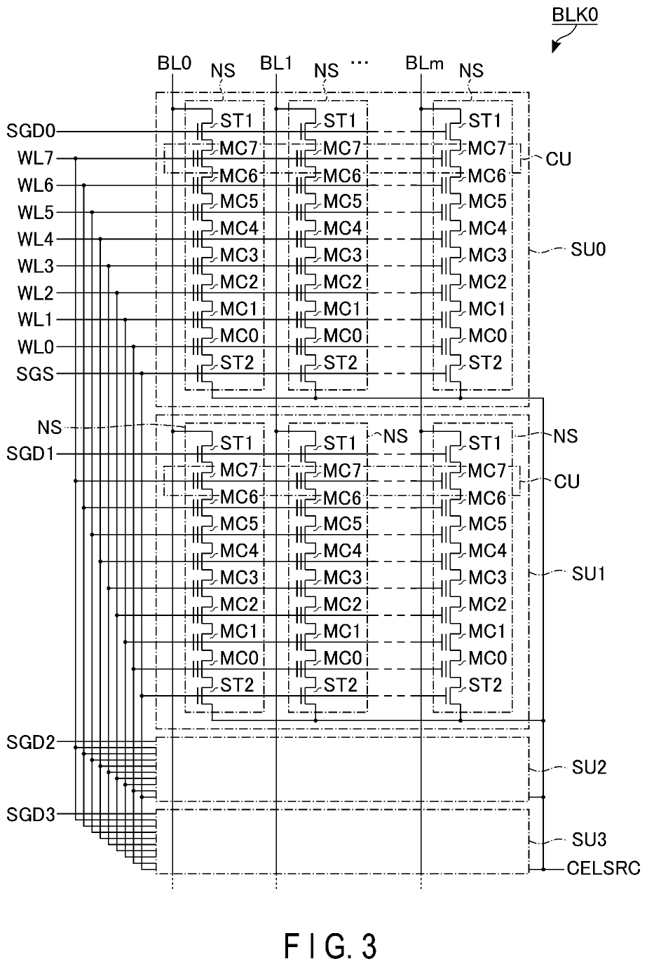

A circuit configuration of the memory cell array 31 will be described with reference to FIG. 3. FIG. 3 is a circuit diagram of the memory cell array 31. FIG. 3 illustrates a circuit configuration of the block BLK0 included in the memory cell array 31 as an example of the circuit configuration of the memory cell array 31. Other blocks BLK1 to BLKn also have the same configuration as that of FIG. 3.

The block BLK includes, for example, four string units SU0 to SU3. Hereinafter, in a case where the string units SU0 to SU3 are not distinguished, they are simply referred to as a string unit SU. The string unit SU is, for example, an aggregate of a plurality of NAND strings NS collectively selected in the write operation or the read operation. The string unit SU includes the NAND strings NS respectively associated with bit lines BL0 to BLm (m is an integer of 1 or more). Hereinafter, in a case where the bit lines BL0 to BLm are not distinguished, they are simply referred to as a bit line BL. The NAND string NS is an aggregate of a plurality of transistors connected in series. The transistors connected in series include, for example, memory cell transistors MC0 to MC7 and select transistors ST1 and ST2. Hereinafter, in a case where the memory cell transistors MC0 to MC7 are not distinguished, they are simply referred to as a memory cell transistor MC. The memory cell transistor MC stores data in a nonvolatile manner. The memory cell transistor MC includes a control gate and a charge storage layer. The select transistors ST1 and ST2 are switching elements. Each of the select transistors ST1 and ST2 is used to select the string unit SU during various operations.

In the NAND string NS, the memory cell transistors MC0 to MC7 are connected in series. The drain of the select transistor ST1 is connected to the associated bit line BL. The source of the select transistor ST1 is connected to one end of the memory cell transistors MC0 to MC7. The drain of the select transistor ST2 is connected to the other end of the memory cell transistors MC0 to MC7. The source of the select transistor ST2 is connected to a source line CELSRC.

In the same block BLK, the control gates of the memory cell transistors MC0 to MC7 are respectively commonly connected to word lines WL0 to WL7. Hereinafter, in a case where the word lines WL0 to WL7 are not distinguished, they are simply referred to as a word line WL. Gates of the respective select transistors ST1 in the string units SU0 to SU3 are respectively commonly connected to select gate lines SGD0 to SGD3. Hereinafter, in a case where the select gate lines SGD0 to SGD3 are not distinguished, they are simply referred to as a select gate line SGD. Gates of the select transistors ST2 included in the same block BLK are commonly connected to a select gate line SGS.

In the circuit configuration of the memory cell array 31 described above, the bit line BL is shared by, for example, the NAND strings NS to which the same column address CAd is allocated in the string units SU. The source line SL is, for example, shared among the blocks BLK.

An aggregate of the memory cell transistors MC connected to the common word line WL in the string unit SU is, for example, referred to as a cell unit CU. The block BLK includes a plurality of the cell units CU. Data stored in the cell unit CU including the memory cell transistors MC each storing 1-bit data according to a threshold voltage corresponds to 1-page data. The cell unit CU can store data of two-page data or more based on the number of bits of the data stored in the memory cell transistor MC.

Further, the circuit configuration of the memory cell array 31 is not limited to the configuration described above. For example, the number of the string units SU included in the block BLK and the number of the memory cell transistors MC and the select transistors ST1 and ST2 included in the NAND string NS may be arbitrary numbers. Hereinafter, the memory cell transistor MC is also referred to as a memory cell MC.

### 1.1.4 Structure of Memory Cell Array

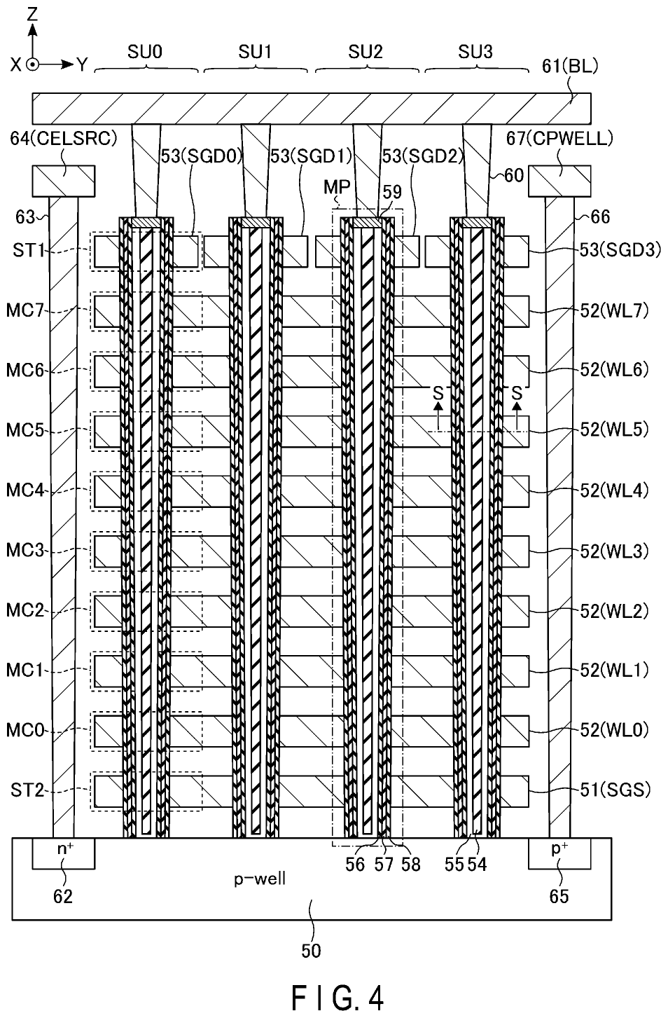

A cross-sectional structure of the memory cell array 31 will be described with reference to FIG. 4. FIG. 4 is a cross-sectional view illustrating an example of the cross-sectional structure of the memory cell array 31. FIG. 4 illustrates a region corresponding to the block BLK. In FIG. 4, the X direction corresponds to an extending direction of the word line WL. The Y direction corresponds to an extending direction of the bit line BL. The Z direction corresponds to a direction perpendicular to a surface of a semiconductor substrate. Note that in the example of FIG. 4, a part of an insulating layer is omitted in order to simplify the description.

A p-type well region (p-well) 50 is provided in the semiconductor substrate. Above the well region 50, an interconnect layer 51 functioning as the select gate line SGS, eight interconnect layers 52 functioning as the word lines WL0 to WL7, and an interconnect layer 53 functioning as the select gate line SGD (SGD0 to SGD3) are separately stacked in this order. That is, above the well region 50, the interconnect layer 51, the eight interconnect layers 52, and the interconnect layer 53 are stacked in this order with the insulating layer (not illustrated) interposed therebetween. The select gate lines SGD0 to SGD3 are arranged in the order of the select gate lines SGD0, SGD1, SGD2, and SGD3 in the Y direction and are apart from each other. The interconnect layers 51 to 53 are made of a conductive material, and includes, for example, tungsten.

In addition, a memory pillar MP, which is a structure forming the select transistors ST1 and ST2 and the memory cell transistors MC0 to MC7, is provided above the well region 50. The memory pillar MP is formed in a columnar shape extending along the Z direction. The memory pillar MP corresponds to the NAND string NS. The memory pillar MP penetrates, for example, the interconnect layer 51, the eight interconnect layers 52, and the interconnect layer 53, and has a bottom surface reaching the p-type well region 50.

Here, an example in which the memory pillar MP is connected to the p-type well region 50 in the semiconductor substrate has been described, but the semiconductor substrate and the memory pillar MP may be formed apart from each other. In a case where the semiconductor substrate and the memory pillar MP are apart from each other, the memory pillar MP is, for example, connected to an n-type semiconductor layer, and the n-type semiconductor layer is, for example, connected to a lamination of tungsten silicide and titanium nitride or a metal layer having aluminum or the like.

In addition, the memory pillar MP includes, for example, a core member 54, a semiconductor layer 55, insulating layers 56 to 58, and a conductor 59.

The core member 54 is formed in a columnar shape extending in the Z direction in a central portion of the memory pillar MP.

A side surface and a lower surface of the core member 54 are covered with the semiconductor layer 55. The semiconductor layer 55 functions as a channel of each of the memory cell transistor MC and the select transistors ST1 and ST2.

A side surface of the semiconductor layer 55 is covered with a layer stack of the insulating layers 56 to 58.

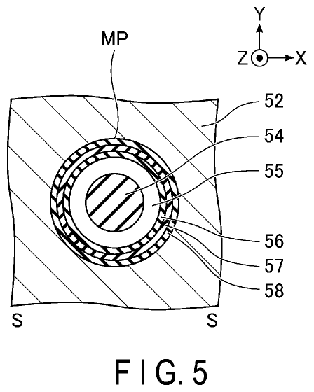

FIG. 5 is a cross-sectional view taken along line S-S of FIG. 4, illustrating an example of a cross-sectional structure of the memory pillar MP.

Specifically, FIG. 5 illustrates the cross-sectional structure of the memory pillar MP in a layer parallel to the surface of the semiconductor substrate and including the interconnect layer 52.

As illustrated in FIG. 5, the insulating layer 56 covers the periphery of the semiconductor layer 55. The insulating layer 56 functions as a tunnel insulating layer of the memory cell transistor MC. The insulating layer 56 is made of an insulating material and includes, for example, silicon oxide or silicon oxynitride. The insulating layer 57 covers the periphery of the insulating layer 56. The insulating layer 57 functions as a charge storage layer of the memory cell transistor MC. The insulating layer 57 is made of an insulating material and includes, for example, silicon nitride. The insulating layer 58 covers the periphery of the insulating layer 57. The insulating layer 58 functions as a block insulating layer of the memory cell transistor MC. The insulating layer 58 is made of an insulating material, and includes, for example, silicon oxide or aluminum oxide. The interconnect layer 52 covers the periphery of the insulating layer 58.

As illustrated in FIG. 4, the conductor 59 is formed on an upper portion of the core member 54 and the semiconductor layer 55. The conductor 59 is electrically connected to the semiconductor layer 55. A side surface of the conductor 59 is covered with, for example, the layer stack of the insulating layers 56 to 58. The conductor 59 can be formed integrally with the semiconductor layer 55.

In the configuration of the memory pillar MP described above, for example, a portion where the memory pillar MP and the interconnect layer 51 intersect each other functions as the select transistor ST2. Portions where the memory pillar MP and the eight interconnect layers 52 intersect each other respectively function as the memory cell transistors MC0 to MC7. A portion where the memory pillar MP and the interconnect layer 53 intersect each other functions as the select transistor ST1.

An upper end of the memory pillar MP is connected to an interconnect layer 61 functioning as the bit line BL via a contact plug 60. The interconnect layer 61 is made of a conductive material, and includes, for example, copper.

An n⁺-type diffusion region 62 into which an n-type impurity is introduced is provided in a surface region of the well region 50. A contact plug 63 is provided on the diffusion region 62, and the contact plug 63 is connected to an interconnect layer 64 functioning as the source line CELSRC. Furthermore, a p⁺-type diffusion region 65 into which a p-type impurity is introduced is provided in the surface region of the well region 50. A contact plug 66 is provided on the diffusion region 65, and the contact plug 66 is connected to an interconnect layer 67 that functions as a well line CPWELL. The well line CPWELL is an interconnect for applying a voltage to the memory pillar MP via the well region 50.

A plurality of the above configurations are arranged in the depth direction (X direction) of the paper surface of FIG. 4, and the string unit SU is constituted by a set of the NAND strings NS arranged in the X direction.

### 1.2 Erase Operation

First, an outline of the erase operation will be described.

The erase operation includes an erase voltage applying operation and an erase verify operation. The erase voltage applying operation is an operation of applying the voltage VERA to the memory cell MC to be erased to lower the threshold voltage of the memory cell MC. The voltage VERA is, for example, a voltage higher than the voltage used in the read operation. The voltage VERA is applied to the memory cell MC via an interconnect (for example, the well line CPWELL, the source line CELSRC, or the bit line 61). The erase verify operation is an operation of determining whether the threshold voltage of the memory cell MC is lower than a target voltage. Hereinafter, in a case where the threshold voltage of the memory cell MC is lower than the target voltage, it is described as “the erase verify operation has been passed”. On the other hand, in a case where the threshold voltage of the memory cell MC is equal to or higher than the target voltage, it is described as “the erase verify operation has failed”. The erase voltage applying operation is typically performed in units of blocks BLK. The erase verify operation is performed in units of string units SU.

The memory controller 10 can separately order the erase voltage applying operation and the erase verify operation to the NAND flash memory 30. For example, another operation such as the write operation or the read operation may be performed between the erase voltage applying operation and the erase verify operation. Further, for example, the block BLK selected in the erase voltage applying operation and the block BLK (string unit SU) selected in the erase verify operation may be different.

In the erase operation, a combination of the erase voltage applying operation and the erase verify operation (hereinafter referred to as an “erase loop”.) is repeatedly performed until the threshold voltage of the memory cell MC becomes lower than the target voltage. Every time the erase loop is repeated, a set value of the voltage VERA in the erase voltage applying operation is stepped up. For example, the set value of the voltage VERA is stepped up by a voltage dVERA. By increasing the voltage VERA stepwise to a final set value in this manner, stress of the erase operation can be reduced as compared with a case where the voltage VERA is increased to the final set value at once. Note that in the erase loop, the erase verify operation may be omitted.

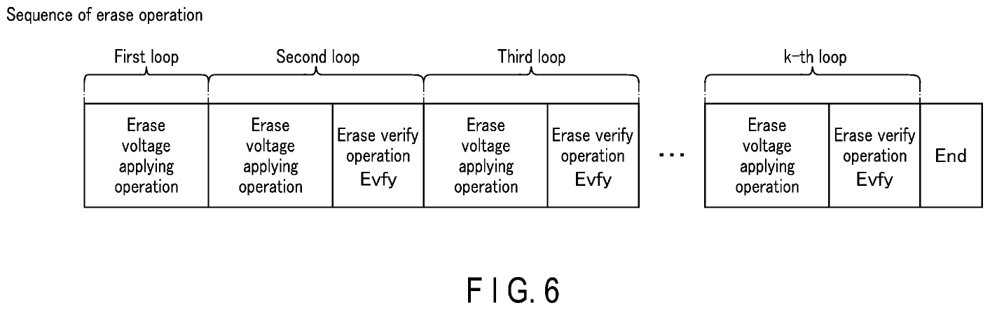

FIG. 6 is a diagram describing an example of a sequence of the erase operation. In the example of FIG. 6, as an example of the erase operation, a case where the erase loop is repeated k times (k is an integer of 2 or more) to end the erase operation is illustrated.

As illustrated in FIG. 6, in a first erase loop (hereinafter also referred to as a “first loop”), the sequencer 36 performs the erase voltage applying operation. After the erase voltage applying operation is performed, the sequencer 36 skips an erase verify operation Evfy (does not perform the erase verify operation). The set value of the voltage VERA in the first erase loop is lower than the set value of the voltage VERA in a second and subsequent erase loops. Therefore, in the first erase loop, the threshold voltage of the memory cell MC is less likely to decrease below the target voltage than in the second and subsequent erase loops. That is, the first erase loop is less likely to pass the erase verify operation than the second and subsequent erase loops. Therefore, in the first erase loop, the erase verify operation can be skipped. By skipping the erase verify operation in this manner, it is possible to suppress an increase in the entire time required for the erase operation. Note that in the first erase loop, the sequencer 36 may perform the erase verify operation.

Next, in the second erase loop (hereinafter also referred to as a “second loop”), the sequencer 36 performs the erase voltage applying operation. The set value of the voltage VERA is stepped up from the set value of the voltage VERA in the erase voltage applying operation of the first erase loop. After the erase voltage applying operation is performed, the sequencer 36 performs the erase verify operation Evfy.

A third erase loop (hereinafter also referred to as a “third loop”) and subsequent erase loops are similar to the second erase loop.

Next, details of the erase operation will be described.

### (Timing Chart)

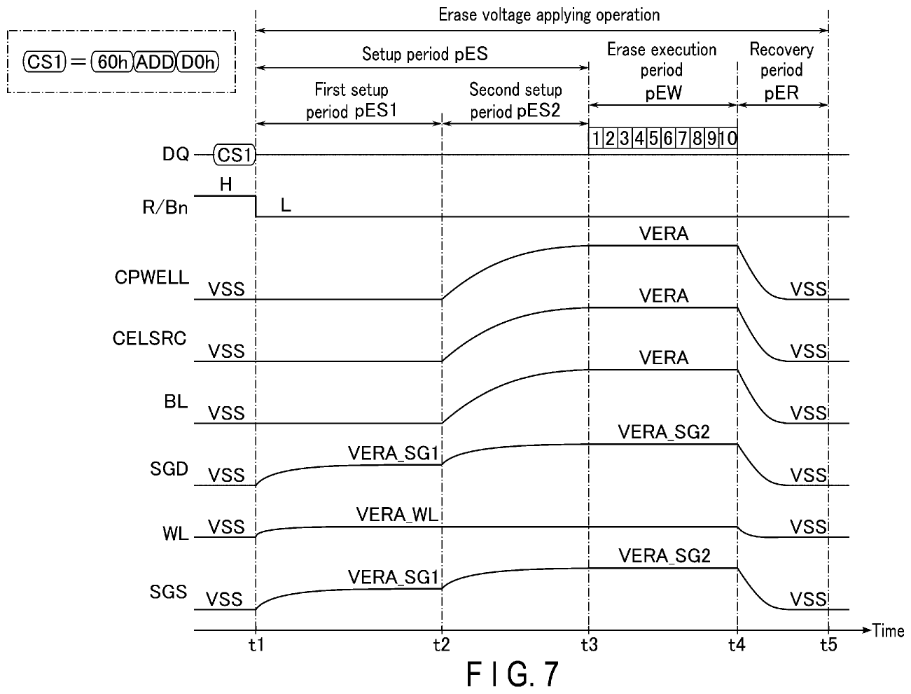

FIG. 7 is a timing chart illustrating an example of the erase operation of the NAND flash memory 30. In the example of FIG. 7, an example of the erase voltage applying operation in the i-th (i is an integer of 1 or more) erase loop is illustrated.

In the present embodiment, before the erase voltage applying operation is performed, voltages of the well line CPWELL, the source line CELSRC, the bit line BL, the select gate lines SGD and SGS, and the word line WL are a voltage VSS (0 V).

In the erase operation, the memory controller 10 transmits, for example, a command set CS1 to the NAND flash memory 30 as the signal DQ. The command set CS1 is, for example, a set of a command and an address including a command “60h”, an address “ADD”, and a command “D0h”. The command “60h” is a command for selecting the block BLK or the like based on the address ADD. The command “D0h” is a command instructing execution of the erase operation based on the address ADD.

As illustrated in FIG. 7, the NAND flash memory 30 receives the command set CS1 from the memory controller 10. At time t1, upon receiving the command set CS1 from the memory controller 10, the sequencer 36 transitions the ready/busy signal RBn from the H level to the L level. Further, the sequencer 36 starts the erase voltage applying operation based on the received command set CS1.

The erase voltage applying operation includes, for example, a setup period pES, an erase execution period pEW, and a recovery period pER.

The setup period pES is a period in which setup of the erase voltage applying operation is performed. The setup period pES further includes a first setup period pES1 and a second setup period pES2. The first setup period pES1 is a period in which the voltages of the select gate lines SGD and SGS and the word line WL are raised (boosted). The second setup period pES2 is a period in which the voltages of the well line CPWELL, the source line CELSRC, the bit line BL, and the select gate lines SGD and SGS are raised (boosted).

The erase execution period pEW is a period in which the voltages of the well line CPWELL, the source line CELSRC, and the bit line BL are raised (completed to be boosted) to the voltage VERA and the threshold voltage of the memory cell MC decreases. For example, in the i-th erase loop, the timer circuit 40 measures, for example, the time during which the voltage VERA is applied, and counts up a count value at regular time intervals. In a case where the count value reaches a predetermined set value (for example, 10), the timer circuit 40 ends the measurement and the count-up. The voltage VERA is applied until the count value becomes 10, that is, 10 periods (hereinafter referred to as “first period”, “second period”, . . . , and “tenth period”) having the same length elapse. The sum of the periods from the first period to the tenth period is, for example, a time during which it can be estimated that the threshold voltage of the memory cell MC has sufficiently decreased. Note that it is sufficient to estimate that the threshold voltage of the memory cell MC has sufficiently decreased, and the set value of the count value, that is, the number of periods during which the voltage VERA is applied is not limited to 10.

The recovery period pER is a period in which the voltages of the well line CPWELL, the source line CELSRC, the bit line BL, the select gate lines SGD and SGS, and the word line WL are lowered (stepped down).

(Setup Period pES)

The setup period pES corresponds to a period from time t1 to time t3. The first setup period pES1 corresponds to a period from time t1 to time t2. The second setup period pES2 corresponds to a period from time t2 to time t3.

At time t1, the row decoder module 38 applies a voltage VERA_SG1 to the select gate lines SGD and SGS and applies a voltage VERA_WL to the word line WL. The voltage VERA_SG1 is a voltage higher than the voltage VSS and lower than a voltage VCC. The voltage VERA_WL is a voltage higher than the voltage VSS and lower than the voltage VERA_SG1. The voltage VERA_SG1 is, for example, about 2 V. The voltage VERA_WL is, for example, 0.5 V. By the application of the voltage VERA_SG1, the voltages of the select gate lines SGD and SGS increase. By the application of the voltage VERA_WL, the voltage of the word line WL increases.

At time t2, the voltages of the select gate lines SGD and SGS become the voltage VERA_SG1. The voltage of the word line WL becomes the voltage VERA_WL. At time t2, the driver module 37 applies the voltage VERA to the well line CPWELL and the source line CELSRC. The sense amplifier module 39 applies the voltage VERA to the bit line BL. The voltage VERA is a voltage higher than the voltage VCC. The final set value of the voltage VERA is, for example, 20 V. By the application of the voltage VERA, the voltages of the well line CPWELL, the source line CELSRC, and the bit line BL increase. In addition, the voltages of the select gate lines SGD and SGS also increase due to coupling. Note that the voltages of the select gate lines SGD and SGS may be increased by the row decoder module 38 applying a voltage VERA_SG2 to be described later to the select gate lines SGD and SGS.

(Erase Execution Period pEW)

The erase execution period pEW corresponds to a period from time t3 to time t4.

At time t3, the voltages of the well line CPWELL, the source line CELSRC, and the bit line BL become the voltage VERA. The voltages of the select gate lines SGD and SGS become the voltage VERA_SG2. The voltage VERA_SG2 is a voltage higher than the voltage VERA_SG1 and lower than the voltage VERA. The voltage VERA_SG2 is, for example, a voltage equal to or higher than the voltage VERA-10 V and equal to or lower than the voltage VERA-5 V. During the period from time t3 to time t4 (the periods from the first period to the tenth period), the voltage VERA is applied to the well line CPWELL, the source line CELSRC, and the bit line BL. The voltage VERA_SG2 is applied to the select gate lines SGD and SGS. A voltage VERA_WL is applied to the word line WL. Thus, the threshold voltage of the memory cell MC decreases.

In a case where the erase execution period pEW is started, the sequencer 36 instructs the timer circuit 40 to measure the time (hereinafter also referred to as a “voltage VERA application time”) during which the voltage VERA is applied to the well line CPWELL. The timer circuit 40 starts measuring the voltage VERA application time based on the instruction received from the sequencer 36. In a case where the tenth period ends, the recovery period pER is started.

(Recovery Period pER)

The recovery period pER corresponds to a period from time t4 to time t5.

At time t4, the driver module 37 applies the voltage VSS to the well line CPWELL and the source line CELSRC. The sense amplifier module 39 applies the voltage VSS to the bit line BL. The row decoder module 38 applies the voltage VSS to the select gate lines SGD and SGS and the word line WL. Thus, the voltages of the well line CPWELL, the source line CELSRC, the bit line BL, the select gate lines SGD and SGS, and the word line WL decrease.

In a case where the recovery period pER is started, the timer circuit 40 ends measuring the voltage VERA application time. The timer circuit 40 transmits the measured time (hereinafter also referred to as a “measurement time”) to the sequencer 36. The sequencer 36 stores the measurement time received from the timer circuit 40 in the latch circuit 41 as the application time information Iat.

At time t5, the voltages of the well line CPWELL, the source line CELSRC, the bit line BL, the select gate lines SGD and SGS, and the word line WL become the voltage VSS. Thus, the erase voltage applying operation ends.

### 1.3 Erase Operation (in a Case where Instruction of Suspension is Received)

In a case where the memory controller 10 receives a request for interrupt processing (for example, the write operation, the read operation, or the like) from the host 2 during the erase operation, the memory controller 10 transmits an instruction to suspend the erase operation to the NAND flash memory 30. Hereinafter, first, an outline of the erase operation in a case where the sequencer 36 receives an instruction of suspension during the erase operation will be described.

For example, in a case where a command “FFh” is received from the memory controller 10 during the erase operation, the sequencer 36 suspends the erase operation. The command “FFh” is a command instructing the NAND flash memory 30 to suspend the operation being processed. After the suspension of the erase operation, the sequencer 36 starts the interrupt processing. In a case where the interrupt processing ends, the sequencer 36 resumes the erase operation. An operation at the time of resumption is determined based on which period in the erase operation the instruction of suspension is received (a timing at which the command “FFh” is received).

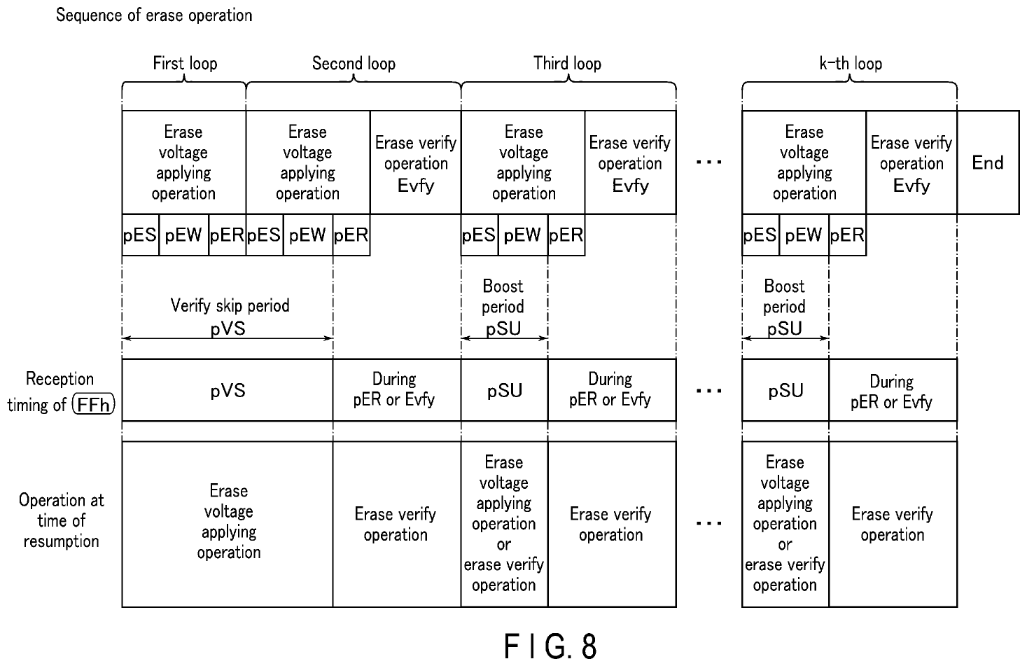

FIG. 8 is a diagram for describing an example of a relationship between a timing at which the instruction of suspension is received during the erase operation and the operation at the time of resuming the erase operation. The sequence of the erase operation is similar to that in FIG. 6. Hereinafter, a period including the setup period pES, the erase execution period pEW, and the recovery period pER of the previous erase voltage applying operation and the setup period pES and the erase execution period pEW of the subsequent erase voltage applying operation in two successively executed erase voltage applying operations is referred to as a “verify skip period pVS”. In the present embodiment, the verify skip period pVS is from the start of the first loop to the erase execution period pEW of the second loop. Note that the verify skip period pVS may be provided after a third loop. Further, a period including the setup period pES and the erase execution period pEW of the erase voltage applying operation other than the verify skip period pVS is referred to as a “boost period pSU”.

As illustrated in FIG. 8, in a case where the command “FFh” is received during the verify skip period pVS, the sequencer 36 performs the erase voltage applying operation as the operation at the time of resumption. In a case where the command “FFh” is received during the recovery period pER or the erase verify operation Evfy, the sequencer 36 performs the erase verify operation as the operation at the time of resumption. In a case where the command “FFh” is received during the boost period pSU, the sequencer 36 performs the erase voltage applying operation or the erase verify operation as the operation at the time of resumption.

Next, details of the erase operation in a case where the sequencer 36 receives the instruction of suspension during the erase operation will be described.

### (Flowchart)

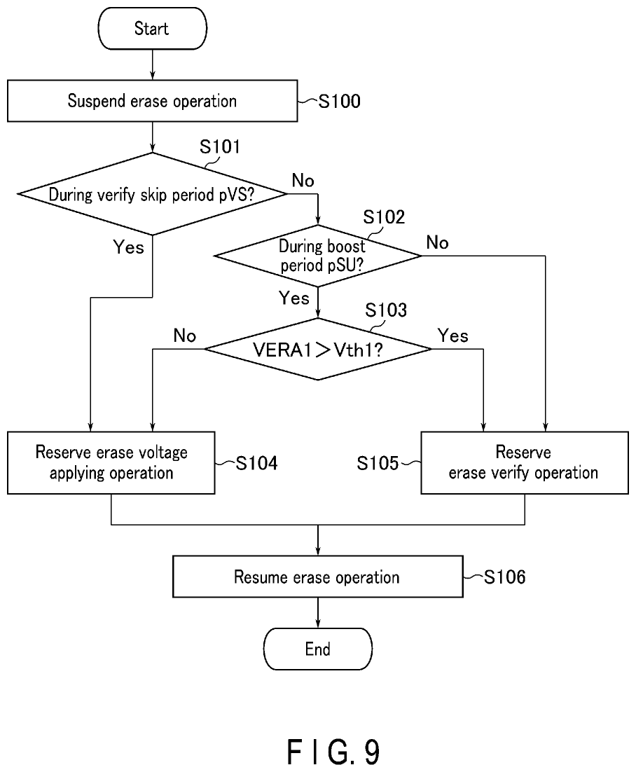

FIG. 9 is a flowchart illustrating an example of the erase operation of the NAND flash memory 30. The example of FIG. 9 illustrates a case where the sequencer 36 receives the command “FFh” during the erase operation. Note that in the present embodiment, an example is given in which the erase operation described below is performed by the sequencer 36, but the erase operation described below may also be performed by the memory controller 10. The same applies to other embodiments and modifications.

Upon receiving the command set CS1 from the memory controller 10, the sequencer 36 starts the erase operation. Upon receiving the command “FFh” from the memory controller 10 after the start of the erase operation, the sequencer 36 suspends the erase operation (S100).

Next, the sequencer 36 determines whether the timing at which the command “FFh” is received is during the verify skip period pVS (S101).

In a case where the verify skip period pVS is in progress (Yes in S101), the sequencer 36 reserves the erase voltage applying operation as the operation at the time of resumption (S104). For example, the sequencer 36 stores as the resumption operation information Iar the “erase voltage applying operation” meaning that the operation at the time of resumption is the erase voltage applying operation, the voltage of the well line CPWELL at the time of suspension (at the time of receiving the command “FFh”), the suspension time, the boost start voltage (the set value of the voltage VERA), and the boost method in the latch circuit 41. In a case where the interrupt processing ends, the sequencer 36 resumes the erase operation (S106). That is, the sequencer 36 performs the reserved erase voltage applying operation. For example, the sequencer 36 acquires the resumption operation information Iar from the latch circuit 41, and performs the erase voltage applying operation based on the acquired resumption operation information Iar.

On the other hand, in a case where the verify skip period pVS is not in progress (No in S101), the sequencer 36 determines whether the timing at which the command “FFh” is received is during the boost period pSU (S102).

In a case where the boost period pSU is not in progress (No in S102), the sequencer 36 reserves the erase verify operation as the operation at the time of resumption (S105). A case where it is not during the boost period pSU includes, for example, a case where it is during the recovery period pER or during the erase verify operation. For example, the sequencer 36 stores the “erase verify operation” meaning that the operation at the time of resumption is the erase verify operation in the latch circuit 41 as the resumption operation information Iar. In a case where the interrupt processing ends, the sequencer 36 resumes the erase operation (S106). That is, the sequencer 36 performs the reserved erase verify operation. For example, the sequencer 36 acquires the resumption operation information Iar from the latch circuit 41, and performs the erase verify operation based on the acquired resumption operation information Iar. In a case where the erase verify operation ends, the sequencer 36 stores an end time of the erase verify operation in the latch circuit 41 as the erase verify operation information Ivfy.

On the other hand, in a case where the boost period pSU is in progress (Yes in S102), the sequencer 36 determines whether the voltage (hereinafter referred to as a “voltage VERA1”) of the well line CPWELL at the time of receiving the command “FFh” is higher than a first threshold value Vth1 (S103). The first threshold value Vth1 is a voltage higher than the voltage VSS and lower than the voltage VERA. The first threshold value Vth1 is determined, for example, as a voltage having a relatively high possibility of not lowering the threshold voltage of the memory cell MC, for example, according to an empirical rule. The first threshold value Vth1 is, for example, 10 V or more and less than 15 V.

In a case where the voltage VERA1 is higher than the first threshold value Vth1 (Yes in S103), the sequencer 36 reserves the erase verify operation as the operation at the time of resumption (S105). In a case where the interrupt processing ends, the sequencer 36 resumes the erase operation (S106). That is, the sequencer 36 performs the reserved erase verify operation.

On the other hand, in a case where the voltage VERA1 is equal to or lower than the first threshold value Vth1 (No in S103), the sequencer 36 reserves the erase voltage applying operation as the operation at the time of resumption (S104). In a case where the interrupt processing ends, the sequencer 36 resumes the erase operation (S106). That is, the sequencer 36 performs the reserved erase voltage applying operation.

As described above, the sequencer 36 performs the erase voltage applying operation or the erase verify operation at the time of resuming the suspended erase operation based on a value of the voltage VERA1 of the well line CPWELL at the time of receiving the command “FFh”. The command “FFh” is not invalidated.

In a case where the voltage VERA1 is equal to or lower than the first threshold value Vth1, there is a relatively high possibility that the threshold voltage of the memory cell MC does not decrease. Therefore, in this case, the sequencer 36 performs the erase voltage applying operation at the time of resumption. On the other hand, in a case where the voltage VERA1 is higher than the first threshold value Vth1, there is a high possibility that the threshold voltage of the memory cell MC decreases as compared with the case where the voltage VERA1 is equal to or lower than the first threshold value Vth1. Therefore, in this case, the sequencer 36 performs the erase verify operation at the time of resumption.

### (Timing Chart)

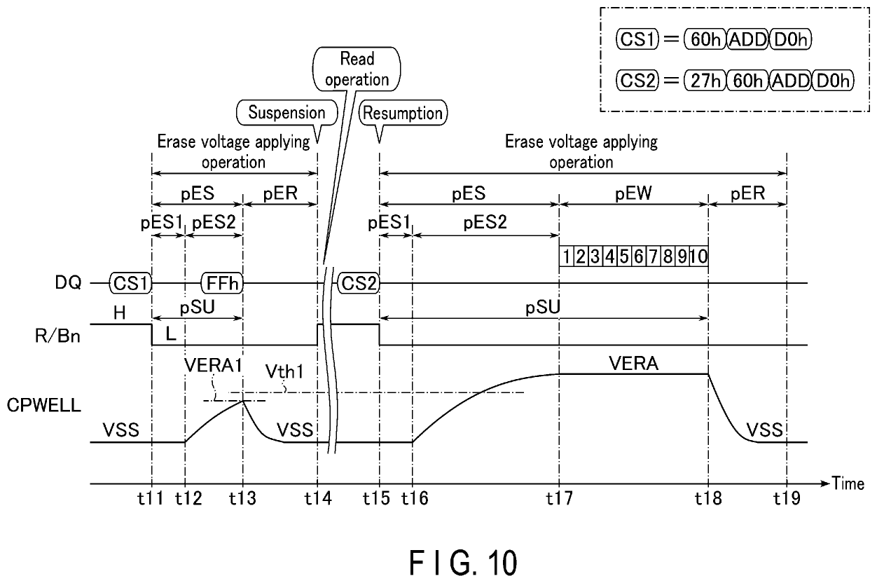

FIG. 10 is a timing chart illustrating an example of the erase operation of the NAND flash memory 30. FIG. 10 illustrates a case where the command “FFh” is received during the boost period pSU in a period in one erase loop other than the verify skip period pVS and the voltage VERA1 of the well line CPWELL at the time of receiving the command “FFh” is equal to or lower than the first threshold value Vth1. Further, in FIG. 10, the interrupt processing is, for example, the read operation. Note that in FIG. 10, the voltages of the source line CELSRC, the bit line BL, the select gate lines SGD and SGS, and the word line WL are omitted. As illustrated in FIG. 7, waveforms of the source line CELSRC and the bit line BL are substantially the same as that of the well line CPWELL.

As illustrated in FIG. 10, in a case where the sequencer 36 receives the command set CS1 from the memory controller 10 at time t1l, the ready/busy signal RBn is transitioned from the H level to the L level. In a case where the ready/busy signal RBn is transitioned to the L level, the sequencer 36 starts the erase voltage applying operation based on the received command set CS1.

An operation in a period from time t1l to time t12 is similar to an operation in the period from time t1 to time t2 in FIG. 7.

At time t12, the driver module 37 applies the voltage VERA to the well line CPWELL and the source line CELSRC. The sense amplifier module 39 applies the voltage VERA to the bit line BL. By the application of the voltage VERA, the voltages of the well line CPWELL, the source line CELSRC, and the bit line BL increase.

Here, for example, it is assumed that the memory controller 10 receives the request for interrupt processing of the read operation from the host 2 in a period from time t12 to time t13. In this case, the memory controller 10 transmits the command “FFh” to the NAND flash memory 30 as the signal DQ.

Upon receiving the command “FFh” from the memory controller 10 at time t13 (during the boost period pSU), the sequencer 36 ends processing of the setup period pES and starts processing of the recovery period pER. The voltage VERA1 of the well line CPWELL at this time is equal to or lower than the first threshold value Vth1.

At time t13, the driver module 37 applies the voltage VSS to the well line CPWELL and the source line CELSRC. The sense amplifier module 39 applies the voltage VSS to the bit line BL. By the application of the voltage VSS, the voltages of the well line CPWELL, the source line CELSRC, and the bit line BL decrease.

In a case where the voltages of the well line CPWELL, the source line CELSRC, the bit line BL, the select gate lines SGD and SGS, and the word line WL are stepped down to the voltage VSS at time t14, the sequencer 36 transits the ready/busy signal RBn from the L level to the H level. Thus, the erase voltage applying operation is suspended, and the interrupt processing is performed.

After the interrupt processing is performed, the memory controller 10 transmits, for example, a command set CS2 to the NAND flash memory 30 as the signal DQ in a period until time t15. The command set CS2 is, for example, a set of a command and an address including a command “27h”, a command “60h”, an address “ADD”, and a command “D0h”. The command “27h” is a command instructing the NAND flash memory 30 to resume the suspended operation.

In a case where the sequencer 36 receives the command set CS2 from the memory controller 10 at time t15, the ready/busy signal RBn is transitioned from the H level to the L level. The sequencer 36 resumes the erase operation based on the received command set CS2. In a case where the voltage VERA1 of the well line CPWELL at the time of receiving the command “FFh” is equal to or lower than the first threshold value Vth1, the sequencer 36 performs the erase voltage applying operation as the operation at the time of resumption.

An operation in a period from time t15 to time t19 is similar to an operation in a period from time t1 to time t5 in FIG. 7. In a case where the tenth period ends, the sequencer 36 deletes, for example, the resumption operation information Iar and the application time information Iat from the latch circuit 41.

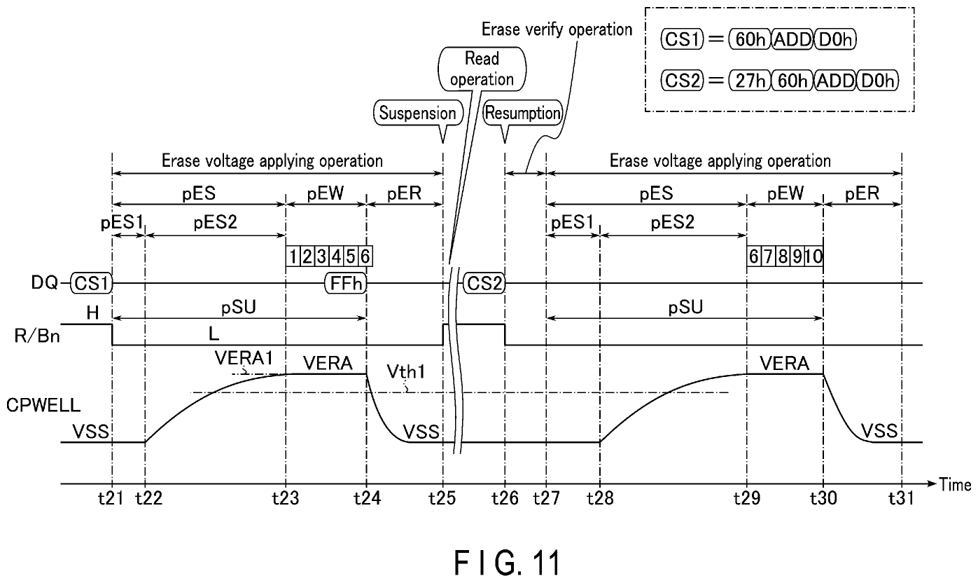

FIG. 11 is a timing chart illustrating another example of the erase operation of the NAND flash memory 30. FIG. 11 illustrates a case where the command “FFh” is received during the boost period pSU in the period in one erase loop other than the verify skip period pVS and the voltage VERA1 of the well line CPWELL at the time of receiving the command “FFh” is higher than the first threshold value Vth1. Further, in FIG. 11, the interrupt processing is, for example, the read operation. Note that in FIG. 11, the voltages of the source line CELSRC, the bit line BL, the select gate lines SGD and SGS, and the word line WL are omitted. As illustrated in FIG. 7, waveforms of the source line CELSRC and the bit line BL are substantially the same as that of the well line CPWELL.

As illustrated in FIG. 11, in a case where the sequencer 36 receives the command set CS1 from the memory controller 10 at time t21, the ready/busy signal RBn is transitioned from the H level to the L level. In a case where the ready/busy signal RBn is transitioned to the L level, the sequencer 36 starts the erase voltage applying operation based on the received command set CS1.

An operation in a period from time t21 to time t24 is similar to an operation in a period from time t1 to time t4 in FIG. 7.

Here, for example, it is assumed that the memory controller 10 receives the request for interrupt processing of the read operation from the host 2 in a period from time t23 to time t24. In this case, the memory controller 10 transmits, for example, the command “FFh” to the NAND flash memory 30 as the signal DQ.

Upon receiving the command “FFh” from the memory controller 10 at time t24 (during the boost period pSU), the timer circuit 40 ends measuring the voltage VERA application time. The timer circuit 40 transmits the measurement time to the sequencer 36. The sequencer 36 stores the measurement time received from the timer circuit 40 in the latch circuit 41 as the application time information Iat. Further, at time t24, the sequencer 36 ends processing of the erase execution period pEW and starts the processing of the recovery period pER. In FIG. 11, the processing ends in the middle of a sixth period in the erase execution period pEW. The voltage VERA1 of the well line CPWELL at this time is higher than the first threshold value Vth1 and equal to the voltage VERA.

An operation in a period from time t24 to time t25 is similar to an operation in the period from time t4 to time t5 in FIG. 7.

In a case where the voltages of the well line CPWELL, the source line CELSRC, the bit line BL, the select gate lines SGD and SGS, and the word line WL are stepped down to the voltage VSS at time t25, the ready/busy signal RBn is transitioned from the L level to the H level. Thus, the erase voltage applying operation is suspended, and the interrupt processing is performed.

After the interrupt processing is performed, the memory controller 10 transmits, for example, the command set CS2 to the NAND flash memory 30 as the signal DQ in a period until time t26.

In a case where the sequencer 36 receives the command set CS2 from the memory controller 10 at time t26, the ready/busy signal RBn is transitioned from the H level to the L level. The sequencer 36 resumes the erase operation based on the received command set CS2. In a case where the voltage VERA1 of the well line CPWELL at the time of receiving the command “FFh” is higher than the first threshold value Vth1, the sequencer 36 performs the erase verify operation as the operation at the time of resumption.

During a period from time t26 to time t27, the sequencer 36 performs the erase verify operation.

An operation in a period from time t27 to time t29 is similar to an operation in the period from time t1 to time t3 in FIG. 7.

The voltage VERA is applied to the well line CPWELL, the source line CELSRC, and the bit line BL in a period from time t29 to time t30 as in the period from time t3 to time t4 in FIG. 7.

At time t29, the sequencer 36 acquires the application time information Iat from the latch circuit 41, and preforms processing of the erase execution period pEW based on the acquired application time information Iat. In the example of FIG. 11, since the processing ends in the middle of the sixth period in the erase execution period pEW from time t23 to time t24, the sequencer 36 performs the processing of the erase execution period pEW from the sixth period to the tenth period. That is, the voltage VERA is applied to the well line CPWELL from the sixth period to the tenth period. In other words, in a case where the erase operation is suspended in the sixth period in the erase execution period pEW in the erase voltage applying operation, the erase execution period pEW is started from the sixth period in the erase voltage applying operation after the erase operation is resumed. In a case where the tenth period ends, the sequencer 36 deletes, for example, the resumption operation information Iar and the application time information Iat from the latch circuit 41. Note that in a case where the processing has not ended until the tenth period, the sequencer 36, for example, does not delete the resumption operation information Iar and the application time information Iat from the latch circuit 41.

An operation in a period from time t30 to time t31 is similar to the operation in the period from time t4 to time t5 in FIG. 7.

### 1.4 Effects According to the Present Embodiment

According to the first embodiment, it is possible to suppress an increase in time required for the erase operation.

In a case where the sequencer 36 receives a suspension command and suspends the erase operation during the erase operation, and performs the erase verify operation and the erase voltage applying operation in this order at the time of resuming the erase operation, there is a possibility that a time until the erase execution period pEW is started after the resumption is longer than that in a case where the erase verify operation is not performed and the erase voltage applying operation is performed at the time of resumption. Therefore, the entire time required for the erase operation may be longer than that in a case where the erase voltage applying operation is performed without performing the erase verify operation at the time of resumption.

In addition, in a case where the sequencer 36 frequently receives the suspension command and suspends the erase operation during the erase operation, and performs the erase verify operation and the erase voltage applying operation in this order every time the erase operation is resumed, the erase operation may not proceed smoothly. In particular, in a case where the suspension command is frequently received during the setup period pES, there is a high possibility that the erase operation does not proceed.

In contrast, in the present embodiment, the sequencer 36 controls whether to perform the erase verify operation based on the voltage VERA1 of the well line CPWELL at the time of receiving the command “FFh” during the boost period pSU of the erase voltage applying operation.

Specifically, in a case where the voltage VERA1 is equal to or lower than the first threshold value Vth1 (a voltage higher than the voltage VSS and lower than the voltage VERA), the sequencer 36 performs the erase voltage applying operation as the operation at the time of resumption. On the other hand, in a case where the voltage VERA1 is higher than the first threshold value Vth1, the sequencer 36 performs the erase verify operation as the operation at the time of resumption. Therefore, the number of times the erase verify operation is performed at the time of resuming the erase operation is reduced as compared with the case where the erase verify operation and the erase voltage applying operation are performed in this order every time the erase operation is resumed. In other words, the time until the erase execution period pEW is started after the resumption can be shortened. Thus, according to the present embodiment, the increase in the entire time required for the erase operation can be suppressed as compared with the case where the erase verify operation and the erase voltage applying operation are performed in this order every time the erase operation is resumed. In addition, according to the present embodiment, it is possible to improve a situation in which the erase operation does not proceed smoothly even in a case where the erase operation is suspended by frequently receiving the suspension command during the erase operation and then the erase operation is resumed. Therefore, even in a case where the command “FFh” is frequently received, it is not necessary to invalidate the command “FFh”.

### 2. Second Embodiment

The semiconductor memory device according to a second embodiment will be described. In the semiconductor memory device according to the second embodiment, the erase operation is different from that of the first embodiment. In the following description, differences from the first embodiment will be mainly described.

### 2.1 Erase Operation (in a Case where Instruction of Suspension is Received)

Details of the erase operation in a case where the sequencer 36 receives the instruction of suspension during the erase operation will be described.

### (Flowchart)

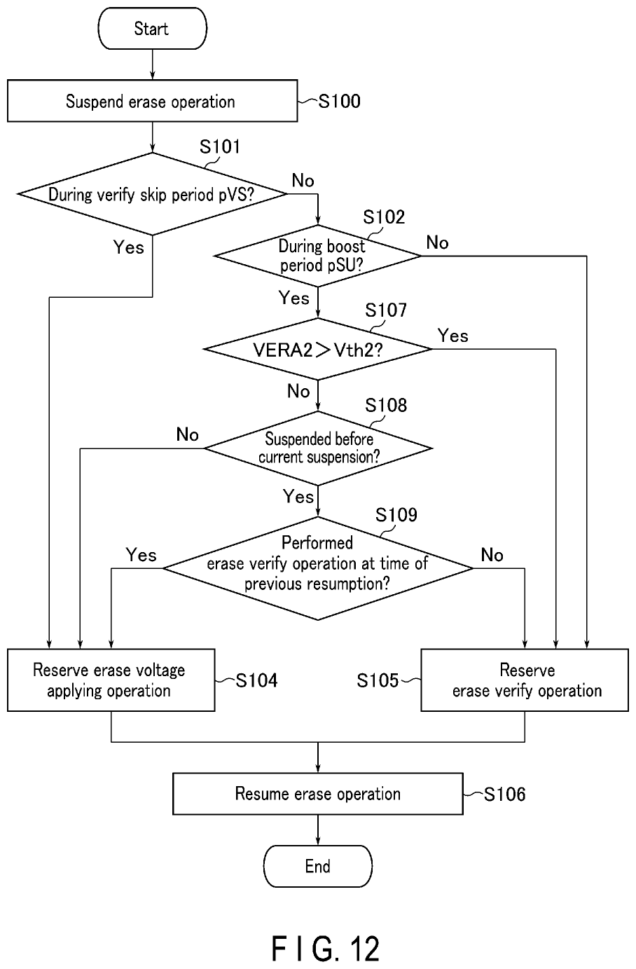

FIG. 12 is a flowchart illustrating an example of the erase operation of the NAND flash memory 30. FIG. 12 illustrates a case where the sequencer 36 receives the command “FFh” during the erase operation as the example of the erase operation. In FIG. 12, step S103 in FIG. 9 illustrated in the first embodiment is replaced with step S107, and steps S108 and S109 are added.

In a case where the boost period pSU is in progress (Yes in S102), the sequencer 36 determines whether the voltage (hereinafter referred to as a “voltage VERA2”) of the well line CPWELL at the time of receiving the command “FFh” is higher than a second threshold value Vth2 (S107). The second threshold value Vth2 is a voltage higher than the first threshold value Vth1 and lower than the voltage VERA. The second threshold value Vth2 is determined as, for example, a voltage having a relatively high possibility of decreasing the threshold voltage of the memory cell MC below the target voltage by an empirical rule. The second threshold value Vth2 is, for example, 15 V or more and less than the voltage VERA.

In a case where the voltage VERA2 is higher than the second threshold value Vth2 (Yes in S107), the sequencer 36 reserves the erase verify operation as the operation at the time of resumption (S105). For example, the sequencer 36 stores the “erase verify operation” meaning that the operation at the time of resumption is the erase verify operation in the latch circuit 41 as the resumption operation information Iar. In a case where the interrupt processing ends, the sequencer 36 resumes the erase operation (S106). That is, the sequencer 36 performs the reserved erase verify operation.

On the other hand, in a case where the voltage VERA2 is equal to or lower than the second threshold value Vth2 (No in S107), the sequencer 36 determines whether the erase operation has been suspended at the voltage VERA2 equal to or lower than the second threshold value Vth2 before the current suspension (hereinafter also referred to as a “first suspension processing”) in one erase loop (S108). For example, the sequencer 36 determines whether the voltage of the well line CPWELL at the time of suspension of the resumption operation information Iar stored in the latch circuit 41 is equal to or lower than the second threshold value Vth2. In a case where the voltage of the well line CPWELL at the time of suspension of the resumption operation information Iar is equal to or lower than the second threshold value Vth2, the sequencer 36 determines that the suspension (hereinafter also referred to as a “second suspension processing”) of the erase operation has been performed when it is before the current suspension (the first suspension processing) and the voltage VERA2 is equal to or lower than the second threshold value Vth2 in one erase loop. In a case where the voltage of the well line CPWELL at the time of suspension of the resumption operation information Iar is higher than the second threshold value Vth2, the sequencer 36 determines that the suspension (the second suspension processing) of the erase operation has not been performed when it is before the current suspension and the voltage VERA2 is equal to or lower than the second threshold value Vth2 in one erase loop.

In one erase loop, in a case where the erase operation has not been suspended at the voltage VERA2 equal to or lower than the second threshold value Vth2 before the current suspension (No in S108), the sequencer 36 reserves the erase voltage applying operation as an operation at the time of the current resumption (at the time of resuming the erase operation suspended by the first suspension processing) (S104). For example, the sequencer 36 stores as the resumption operation information Iar the “erase voltage applying operation” meaning that the operation at the time of resumption is the erase voltage applying operation, the voltage (voltage VERA2) of the well line CPWELL at the time of suspension, the suspension time, the boost start voltage (the set value of voltage VERA), and the boost method in the latch circuit 41. In a case where the interrupt processing ends, the sequencer 36 resumes the erase operation (S106). That is, the sequencer 36 performs the reserved erase voltage applying operation.

On the other hand, in one erase loop, in a case where the erase operation has been suspended at the voltage VERA2 equal to or lower than the second threshold value Vth2 before the current suspension (Yes in S108), the sequencer 36 determines whether the erase verify operation has been performed at the time of the previous resumption (at the time of resuming the erase operation suspended by the second suspension processing) (S109). For example, the sequencer 36 acquires the resumption operation information Iar from the latch circuit 41, and determines whether the erase verify operation has been performed at the time of the previous resumption based on the acquired resumption operation information Iar.

In a case where the erase verify operation has been performed at the time of the previous resumption (Yes in S109), the sequencer 36 reserves the erase voltage applying operation as the operation at the time of the current resumption (S104). In a case where the interrupt processing ends, the sequencer 36 resumes the erase operation (S106). That is, the sequencer 36 performs the reserved erase voltage applying operation.

On the other hand, in a case where the erase verify operation has not been performed at the time of the previous resumption (No in S109), the sequencer 36 reserves the erase verify operation as the operation at the time of the current resumption (S105). In other words, in the period in one erase loop other than the verify skip period pVS, in a case where a situation in which the voltage VERA2 of the well line CPWELL when the sequencer 36 receives the command “FFh” during the boost period pSU is equal to or lower than the second threshold value Vth2 is repeated twice, and the erase verify operation has not been performed, the sequencer 36 reserves the erase verify operation as the operation at the time of the current resumption. In a case where the interrupt processing ends, the sequencer 36 resumes the erase operation (S106). That is, the sequencer 36 performs the reserved erase verify operation.

As described above, the sequencer 36 performs the erase voltage applying operation or the erase verify operation at the time of resuming the suspended erase operation based on a value of the voltage VERA2 of the well line CPWELL at the time of receiving the command “FFh” and the number of suspensions at the voltage VERA2 equal to or lower than the second threshold value Vth2 in one erase loop. The command “FFh” is not invalidated.

In a case where the voltage VERA2 is higher than the second threshold value Vth2, there is a relatively high possibility that the threshold voltage of the memory cell MC decreases lower than the target voltage. Therefore, in this case, the sequencer 36 performs the erase verify operation at the time of resumption.

In a case where the voltage VERA2 is equal to or lower than the second threshold value Vth2, the threshold voltage of the memory cell MC is less likely to decrease lower than the target voltage as compared with a case where the voltage VERA2 is higher than the second threshold value Vth2. However, in a case where the erase operation has been continuously suspended twice at the voltage VERA2 equal to or lower than the second threshold value Vth2 in one erase loop, and the erase verify operation is not performed at the time of resumption after the previous suspension, even if the threshold voltage of the memory cell MC decreases lower than the target voltage in the erase voltage applying operation at the time of resumption after the previous suspension, this may not be detected. In this case, the threshold voltage of the memory cell MC may excessively decrease. Therefore, in a case where the erase operation has not been continuously suspended twice at the voltage VERA2 equal to or lower than the second threshold value Vth2 in one erase loop, the sequencer 36 performs the erase voltage applying operation at the time of resumption. In a case where the erase operation has been continuously suspended twice at the voltage VERA2 equal to or lower than the second threshold value Vth2 in one erase loop and the erase verify operation has been performed at the time of resumption after the previous suspension, the sequencer 36 performs the erase voltage applying operation at the time of the current resumption. In a case where the erase operation has been continuously suspended twice at the voltage VERA2 equal to or lower than the second threshold value Vth2 in one erase loop and the erase verify operation has not been performed at the time of resumption after the previous suspension, the sequencer 36 performs the erase verify operation at the time of the current resumption.

Note that in a case where the voltage VERA2 of the well line CPWELL is equal to or lower than the second threshold value Vth2, and the second suspension processing of suspending the erase operation has been performed p times (p is an integer of 2 or more) when it is before the first suspension processing and the voltage VERA2 is equal to or lower than the second threshold value Vth2 in one erase loop, the erase voltage applying operation or the erase verify operation may be performed at the time of resuming the erase operation suspended by the first suspension processing. In a case where the second suspension processing has not been performed p times when it is before the first suspension processing and the voltage VERA2 is equal to or lower than the second threshold value Vth2 in one erase loop, the erase voltage applying operation may be performed at the time of resuming the erase operation suspended by the first suspension processing.

### (Timing Chart)

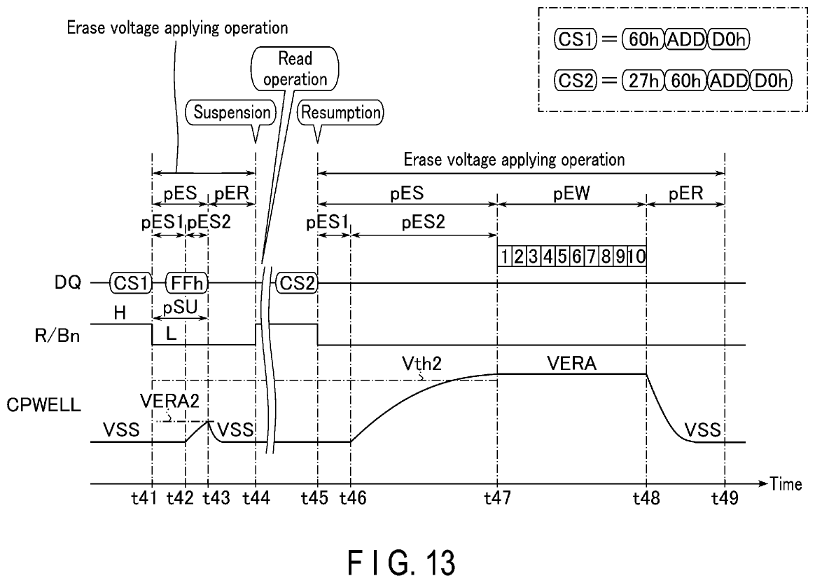

FIG. 13 is a timing chart illustrating an example of the erase operation of the NAND flash memory 30. FIG. 13 illustrates a case where the command “FFh” is received during the boost period pSU in the period in one erase loop other than the verify skip period pVS and the voltage VERA2 of the well line CPWELL at the time of receiving the command “FFh” is equal to or lower than the second threshold value Vth2. Further, in FIG. 13, the interrupt processing is, for example, the read operation. Note that in FIG. 13, the voltages of the source line CELSRC, the bit line BL, the select gate lines SGD and SGS, and the word line WL are omitted. As illustrated in FIG. 7, waveforms of the source line CELSRC and the bit line BL are substantially the same as that of the well line CPWELL.

As illustrated in FIG. 13, in a case where the sequencer 36 receives the command set CS1 from the memory controller 10 at time t41, the ready/busy signal RBn is transitioned from the H level to the L level. The sequencer 36 starts the erase voltage applying operation based on the received command set CS1.

An operation in a period from time t41 to time t42 is similar to the operation in the period from time t1 to time t2 in FIG. 7.

At time t42, the driver module 37 applies the voltage VERA to the well line CPWELL and the source line CELSRC. The sense amplifier module 39 applies the voltage VERA to the bit line BL. By the application of the voltage VERA, the voltages of the well line CPWELL, the source line CELSRC, and the bit line BL increase.

Here, for example, it is assumed that the memory controller 10 receives the request for interrupt processing of the read operation from the host 2 in a period from time t42 to time t43. In this case, the memory controller 10 transmits, for example, the command “FFh” to the NAND flash memory 30 as the signal DQ.

Upon receiving the command “FFh” from the memory controller 10 at time t43 (during the boost period pSU), the sequencer 36 ends the processing of the setup period pES and starts the processing of the recovery period pER. The voltage VERA2 of the well line CPWELL at this time is equal to or lower than the second threshold value Vth2.

At time t43, the driver module 37 applies the voltage VSS to the well line CPWELL and the source line CELSRC. The sense amplifier module 39 applies the voltage VSS to the bit line BL. By the application of the voltage VSS, the voltages of the well line CPWELL, the source line CELSRC, and the bit line BL decrease.

In a case where the voltages of the well line CPWELL, the source line CELSRC, the bit line BL, the select gate lines SGD and SGS, and the word line WL are stepped down to the voltage VSS at time t44, the ready/busy signal RBn is transitioned from the L level to the H level. Thus, the erase voltage applying operation is suspended, and the interrupt processing is performed.

After the interrupt processing is performed, the memory controller 10 transmits, for example, the command set CS2 to the NAND flash memory 30 as the signal DQ in a period until time t45.

In a case where the sequencer 36 receives the command set CS2 from the memory controller 10 at time t45, the ready/busy signal RBn is transitioned from the H level to the L level. The sequencer 36 resumes the erase operation based on the received command set CS2. In a case where the voltage VERA2 of the well line CPWELL at the time of receiving the command “FFh” is equal to or lower than the second threshold value Vth2, the sequencer 36 performs the erase voltage applying operation as the operation at the time of resumption.

An operation in a period from time t45 to time t49 is similar to the operation in the period from time t1 to time t5 in FIG. 7. In a case where the tenth period ends, the sequencer 36 deletes, for example, the resumption operation information Iar and the application time information Iat from the latch circuit 41.

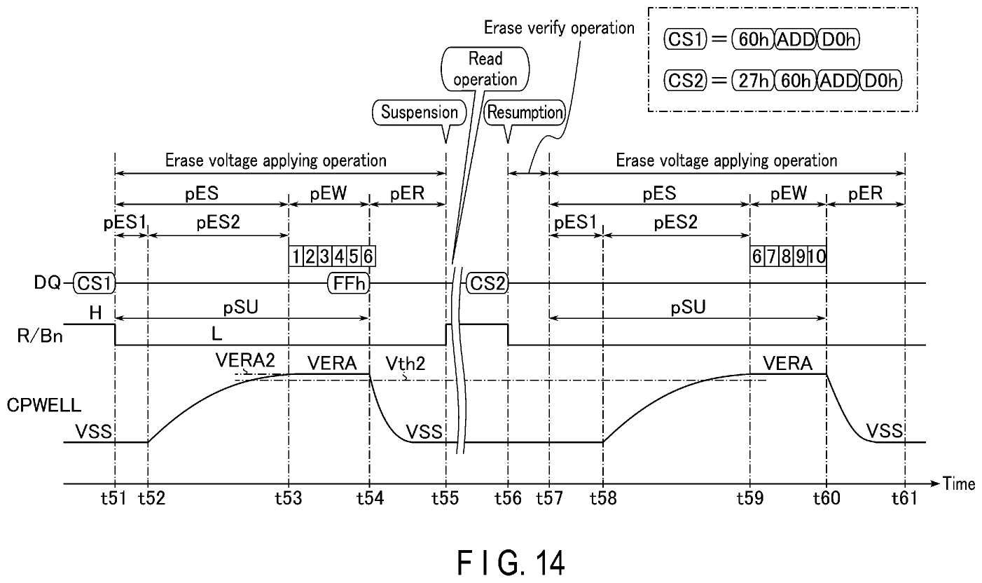

FIG. 14 is a timing chart illustrating another example of the erase operation of the NAND flash memory 30. FIG. 14 illustrates a case where the command “FFh” is received during the boost period pSU in the period in one erase loop other than the verify skip period pVS and the voltage VERA2 of the well line CPWELL at the time of receiving the command “FFh” is higher than the second threshold value Vth2. Further, in FIG. 14, the interrupt processing is, for example, the read operation. Note that in FIG. 14, the voltages of the source line CELSRC, the bit line BL, the select gate lines SGD and SGS, and the word line WL are omitted. As illustrated in FIG. 7, waveforms of the source line CELSRC and the bit line BL are substantially the same as that of the well line CPWELL.

As illustrated in FIG. 14, in a case where the sequencer 36 receives the command set CS1 from the memory controller 10 at time t51, the ready/busy signal RBn is transitioned from the H level to the L level. In a case where the ready/busy signal RBn is transitioned to the L level, the sequencer 36 starts the erase voltage applying operation based on the received command set CS1.

An operation in a period from time t51 to time t54 is similar to an operation in the period from time t21 to time t24 in FIG. 11.

Here, for example, it is assumed that the memory controller 10 receives the request for interrupt processing of the read operation from the host 2 in a period from time t53 to time t54. In this case, the memory controller 10 transmits, for example, the command “FFh” to the NAND flash memory 30 as the signal DQ.

Upon receiving the command “FFh” from the memory controller 10 at time t54 (during the boost period pSU), the sequencer 36 ends the processing of the erase execution period pEW and starts the processing of the recovery period pER. The voltage VERA2 of the well line CPWELL at this time is higher than the second threshold value Vth2 and equal to the voltage VERA.

An operation in a period from time t54 to time t55 is similar to the operation in the period from time t4 to time t5 in FIG. 7.

In a case where the voltages of the well line CPWELL, the source line CELSRC, the bit line BL, the select gate lines SGD and SGS, and the word line WL are stepped down to the voltage VSS at time t55, the ready/busy signal RBn is transitioned from the L level to the H level. Thus, the erase voltage applying operation is suspended, and the interrupt processing is performed.

After the interrupt processing is performed, the memory controller 10 transmits, for example, the command set CS2 to the NAND flash memory 30 as the signal DQ in a period until time t56.

In a case where the sequencer 36 receives the command set CS2 from the memory controller 10 at time t56, the ready/busy signal RBn is transitioned from the H level to the L level. The sequencer 36 resumes the erase operation based on the received command set CS2. In a case where the voltage VERA2 of the well line CPWELL at the time of receiving the command “FFh” is higher than the second threshold value Vth2, the sequencer 36 performs the erase verify operation as the operation at the time of resumption.

During a period from time t56 to time t57, the sequencer 36 performs the erase verify operation.

An operation in a period from time t57 to time t61 is similar to an operation in a period from time t27 to time t31 in FIG. 11. In the case where the tenth period ends, the sequencer 36 deletes, for example, the resumption operation information Iar and the application time information Iat from the latch circuit 41.

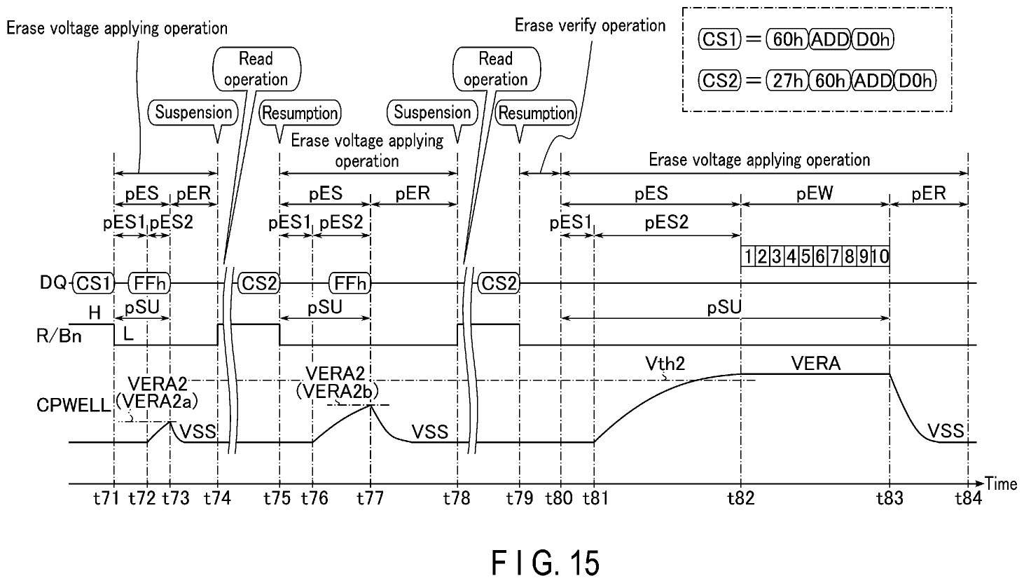

FIG. 15 is a timing chart illustrating another example of the erase operation of the NAND flash memory 30. FIG. 15 illustrates a case where the erase operation is suspended by receiving the command “FFh” during a certain boost period pSU in the period in one erase loop other than the verify skip period pVS, and the command “FFh” is received during the boost period pSU after the erase operation is resumed. Further, in FIG. 15, the interrupt processing is, for example, the read operation. Note that in FIG. 15, the voltages of the source line CELSRC, the bit line BL, the select gate lines SGD and SGS, and the word line WL are omitted. As illustrated in FIG. 7, waveforms of the source line CELSRC and the bit line BL are substantially the same as that of the well line CPWELL.

As illustrated in FIG. 15, in a case where the sequencer 36 receives the command set CS1 from the memory controller 10 at time t71, the ready/busy signal RBn is transitioned from the H level to the L level. The sequencer 36 starts the erase voltage applying operation based on the received command set CS1.

An operation in a period from time t71 to time t72 is similar to the operation in the period from time t1 to time t2 in FIG. 7.

At time t72, the driver module 37 applies the voltage VERA to the well line CPWELL and the source line CELSRC. The sense amplifier module 39 applies the voltage VERA to the bit line BL. By the application of the voltage VERA, the voltages of the well line CPWELL, the source line CELSRC, and the bit line BL increase.

Here, for example, it is assumed that the memory controller 10 receives the request for interrupt processing of the read operation from the host 2 in a period from time t72 to time t73. In this case, the memory controller 10 transmits, for example, the command “FFh” to the NAND flash memory 30 as the signal DQ.

Upon receiving the command “FFh” from the memory controller 10 at time t73 (during the boost period pSU), the sequencer 36 ends the processing of the setup period pES and starts the processing of the recovery period pER. The voltage VERA2 (hereinafter also referred to as a “voltage VERA2a”) of the well line CPWELL at this time is equal to or lower than the second threshold value Vth2.

At time t73, the driver module 37 applies the voltage VSS to the well line CPWELL and the source line CELSRC. The sense amplifier module 39 applies the voltage VSS to the bit line BL. By the application of the voltage VSS, the voltages of the well line CPWELL, the source line CELSRC, and the bit line BL decrease.

In a case where the voltages of the well line CPWELL, the source line CELSRC, the bit line BL, the select gate lines SGD and SGS, and the word line WL are stepped down to the voltage VSS at time t74, the ready/busy signal RBn is transitioned from the L level to the H level. Thus, the erase voltage applying operation is suspended, and the interrupt processing is performed.

After the interrupt processing is performed, the memory controller 10 transmits, for example, the command set CS2 to the NAND flash memory 30 as the signal DQ in a period until time t75.

In a case where the sequencer 36 receives the command set CS2 from the memory controller 10 at time t75, the ready/busy signal RBn is transitioned from the H level to the L level. The sequencer 36 resumes the erase operation based on the received command set CS2. In a case where the voltage VERA2 (VERA2a) of the well line CPWELL at the time of receiving the command “FFh” is equal to or lower than the second threshold value Vth2, the sequencer 36 performs the erase voltage applying operation as the operation at the time of resumption.

An operation in a period from time t75 to time t76 is similar to the operation in the period from time t1 to time t2 in FIG. 7.

At time t76, the driver module 37 applies the voltage VERA to the well line CPWELL and the source line CELSRC. The sense amplifier module 39 applies the voltage VERA to the bit line BL. By the application of the voltage VERA, the voltages of the well line CPWELL, the source line CELSRC, and the bit line BL increase.

Here, for example, it is assumed that the memory controller 10 receives the request for interrupt processing of the read operation from the host 2 in a period from time t76 to time t77. In this case, the memory controller 10 transmits, for example, the command “FFh” to the NAND flash memory 30 as the signal DQ.

Upon receiving the command “FFh” from the memory controller 10 at time t77 (during the boost period pSU), the sequencer 36 ends the processing of the setup period pES and starts the processing of the recovery period pER. The voltage VERA2 (hereinafter also referred to as a “voltage VERA2b”) of the well line CPWELL at this time is equal to or lower than the second threshold value Vth2.

At time t77, the driver module 37 applies the voltage VSS to the well line CPWELL and the source line CELSRC. The sense amplifier module 39 applies the voltage VSS to the bit line BL. By the application of the voltage VSS, the voltages of the well line CPWELL, the source line CELSRC, and the bit line BL decrease.

In a case where the voltages of the well line CPWELL, the source line CELSRC, the bit line BL, the select gate lines SGD and SGS, and the word line WL are stepped down to the voltage VSS at time t78, the ready/busy signal RBn is transitioned from the L level to the H level. Thus, the erase voltage applying operation is suspended, and the interrupt processing is performed.

After the interrupt processing is performed, the memory controller 10 transmits, for example, the command set CS2 to the NAND flash memory 30 as the signal DQ in a period until time t79.

In a case where the sequencer 36 receives the command set CS2 from the memory controller 10 at time t79, the ready/busy signal RBn is transitioned from the H level to the L level. The sequencer 36 resumes the erase operation based on the received command set CS2. In the period in one erase loop other than the verify skip period pVS, in a case where a situation in which the voltage VERA2 of the well line CPWELL when the sequencer 36 receives the command “FFh” during the boost period pSU is equal to or lower than the second threshold value Vth2 is repeated twice, the sequencer 36 performs the erase verify operation as the operation at the time of resumption. Note that in the period in one erase loop other than the verify skip period pVS, in a case a situation in which the voltage VERA2 of the well line CPWELL when the sequencer 36 receives the command “FFh” during the boost period pSU is equal to or lower than the second threshold value Vth2 is repeated three or more times, the erase verify operation may be performed as the operation at the time of resumption.

During a period from time t79 to time t80, the sequencer 36 performs the erase verify operation.

An operation in a period from time t80 to time t84 is similar to the operation in the period from time t1 to time t5 in FIG. 7. In a case where the tenth period ends, the sequencer 36 deletes, for example, the resumption operation information Iar and the application time information Iat from the latch circuit 41.

### 2.2 Effects According to the Present Embodiment

According to the second embodiment, the same effects as those of the first embodiment are obtained.

Further, in the present embodiment, in a case where the voltage VERA2 is equal to or lower than the second threshold value Vth2 (a voltage higher than the first threshold value Vth1 and lower than voltage VERA), the sequencer 36 performs the erase voltage applying operation as the operation at the time of resumption. In a case where the voltage VERA2 is higher than the second threshold value Vth2, the sequencer 36 performs the erase verify operation as the operation at the time of resumption. Even if the voltage VERA2 is equal to or lower than the second threshold value Vth2, in the period in one erase loop other than the verify skip period pVS, in a case where a situation in which the voltage VERA2 is equal to or lower than the second threshold value Vth2 is repeated twice, the sequencer 36 performs the erase verify operation as the operation at the time of resumption. Therefore, according to the present embodiment, it is possible to suppress excessive decrease of the threshold voltage of the memory cell MC.

### 3. Third Embodiment

The semiconductor memory device according to a third embodiment will be described. In the semiconductor memory device according to the third embodiment, the erase operation is different from that of the second embodiment. In the following description, differences from the second embodiment will be mainly described.

### 3.1 Erase Operation (in a Case where Instruction of Suspension is Received)

Details of the erase operation in a case where the sequencer 36 receives the instruction of suspension during the erase operation will be described.

### (Flowchart)

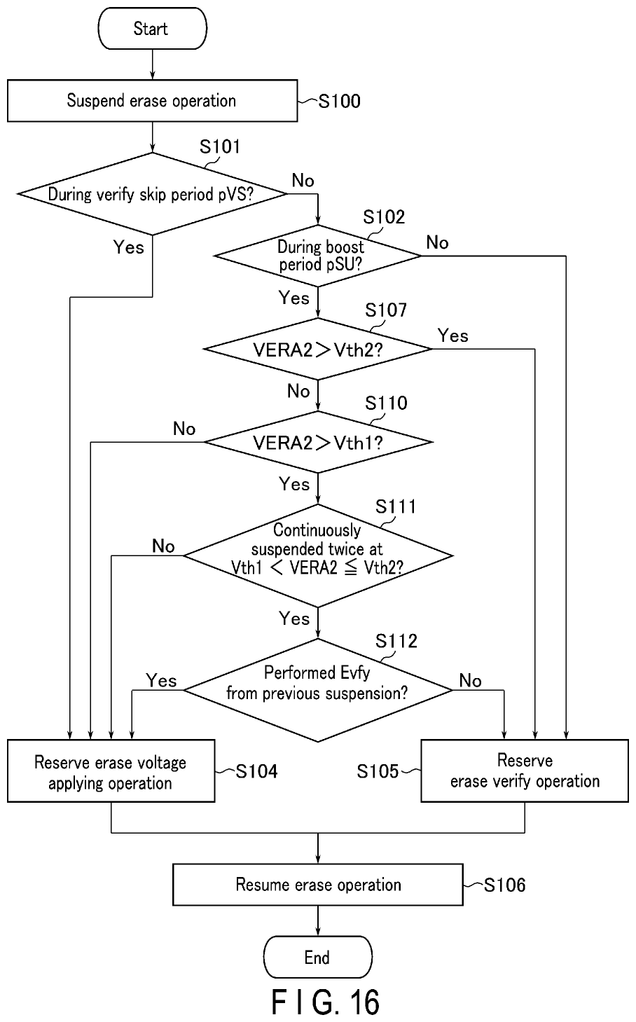

FIG. 16 is a flowchart illustrating an example of the erase operation of the NAND flash memory 30. FIG. 16 illustrates a case where the sequencer 36 receives the command “FFh” during the erase operation as the example of the erase operation. In FIG. 16, steps S108 and S109 in FIG. 12 illustrated in the second embodiment are replaced with steps S110 to S112.

In a case where the voltage VERA2 is equal to or lower than the second threshold value Vth2 (No in S107), the sequencer 36 determines whether the voltage VERA2 is higher than the first threshold value Vth1 (S110). The first threshold value Vth1 is a value similar to the first threshold value Vth1 described in the first embodiment. The second threshold value Vth2 is a value similar to the second threshold value Vth2 described in the second embodiment.

In a case where the voltage VERA2 is equal to or lower than the first threshold value Vth1 (No in S110), the sequencer 36 reserves the erase voltage applying operation as the operation at the time of resumption (S104).

On the other hand, in a case where the voltage VERA2 is higher than the first threshold value Vth1 (Yes in S110), the sequencer 36 determines whether the erase operation has been continuously suspended twice at the voltage VERA2 satisfying “first threshold value Vth1<voltage VERA2≤second threshold value Vth2” in one erase loop (Sill). The determination method is, for example, similar to that of the second embodiment.

In a case where the erase operation has not been continuously suspended twice in one erase loop (No in S111), the sequencer 36 reserves the erase voltage applying operation as the operation at the time of resumption (S104).

On the other hand, in a case where the erase operation has been continuously suspended twice in one erase loop (Yes in S111), the sequencer 36 determines whether the erase verify operation has been performed from the previous suspension (the second suspension processing) to the current suspension (the first suspension processing) (S112). For example, the sequencer 36 determines whether the end time of the erase verify operation information Ivfy stored in the latch circuit 41 is between the suspension time of the resumption operation information Iar stored in the latch circuit 41 and the current time. In a case where the end time of the erase verify operation information Ivfy is between the suspension time of the resumption operation information Iar and the current time, the sequencer 36 determines that the erase verify operation has been performed from the previous suspension to the current suspension. In a case where the end time of the erase verify operation information Ivfy is not between the suspension time of the resumption operation information Iar and the current time, the sequencer 36 determines that the erase verify operation has not been performed from the previous suspension to the current suspension.

In a case where the erase verify operation has been performed from the previous suspension to the current suspension (Yes in S112), the sequencer 36 reserves the erase voltage applying operation as the operation at the time of resumption (S104).

On the other hand, in a case where the erase verify operation has not been performed from the previous suspension to the current suspension (No in S112), the sequencer 36 reserves the erase verify operation as the operation at the time of resumption (S105).

As described above, the sequencer 36 performs the erase voltage applying operation or the erase verify operation at the time of resuming the suspended erase operation based on the value of the voltage VERA2 of the well line CPWELL at the time of receiving the command “FFh”, the number of suspensions at the voltage VERA2 satisfying “first threshold value Vth1<voltage VERA2≤second threshold value Vth2” in one erase loop, and whether the erase verify operation has been performed from the previous suspension to the current suspension. The command “FFh” is not invalidated.

In a case where the voltage VERA2 is higher than the second threshold value Vth2, there is a relatively high possibility that the threshold voltage of the memory cell MC decreases lower than the target voltage. Therefore, in this case, the sequencer 36 performs the erase verify operation at the time of resumption.

In a case where the voltage VERA2 is higher than the first threshold value Vth1 and equal to or lower than the second threshold value Vth2, the threshold voltage of the memory cell MC is less likely to decrease lower than the target voltage as compared with the case where the voltage VERA2 is higher than the second threshold value Vth2. However, in a case where the erase operation has been continuously suspended twice at the voltage VERA2 satisfying “first threshold value Vth1<voltage VERA2≤second threshold value Vth2” in one erase loop, and the erase verify operation has not been performed from the previous suspension to the current suspension, even if the threshold voltage of the memory cell MC decreases lower than the target voltage in the erase voltage applying operation at the time of resumption after the previous suspension, this may not be detected. In this case, the threshold voltage of the memory cell MC may excessively decrease. Therefore, in a case where the erase operation has not been continuously suspended twice at the voltage VERA2 satisfying “first threshold value Vth1<voltage VERA2≤second threshold value Vth2” in one erase loop, the sequencer 36 performs the erase voltage applying operation at the time of resumption. In a case where the erase operation has been continuously suspended twice at the voltage VERA2 satisfying “first threshold value Vth1<voltage VERA2≤second threshold value Vth2” in one erase loop and the erase verify operation has been performed from the previous suspension to the current suspension, the sequencer 36 performs the erase voltage applying operation at the time of the current resumption. In a case where the erase operation has been continuously suspended twice at the voltage VERA2 satisfying “first threshold value Vth1<voltage VERA2≤second threshold value Vth2” in one erase loop and the erase verify operation has not been performed from the previous suspension to the current suspension, the sequencer 36 performs the erase verify operation at the time of the current resumption.

In a case where the voltage VERA2 is equal to or lower than the first threshold value Vth1, there is a relatively high possibility that the threshold voltage of the memory cell MC does not decrease. Therefore, in this case, the sequencer 36 performs the erase voltage applying operation at the time of resumption.

Note that in a case where the voltage VERA2 of the well line CPWELL is higher than the first threshold value Vth1 and equal to or lower than the second threshold value Vth2, and the second suspension processing of suspending the erase operation has been performed p times (p is an integer of 2 or more) when it is before the first suspension processing and the voltage VERA2 is higher than the first threshold value Vth1 and equal to or lower than the second threshold value Vth2 in one erase loop, the erase voltage applying operation or the erase verify operation may be performed at the time of resuming the erase operation suspended by the first suspension processing. In a case where the second suspension processing has not been performed p times when it is before the first suspension processing and the voltage VERA2 is higher than the first threshold value Vth1 and equal to or lower than the second threshold value Vth2 in one erase loop, the erase voltage applying operation may be performed at the time of resuming the erase operation suspended by the first suspension processing.

### (Timing Chart)

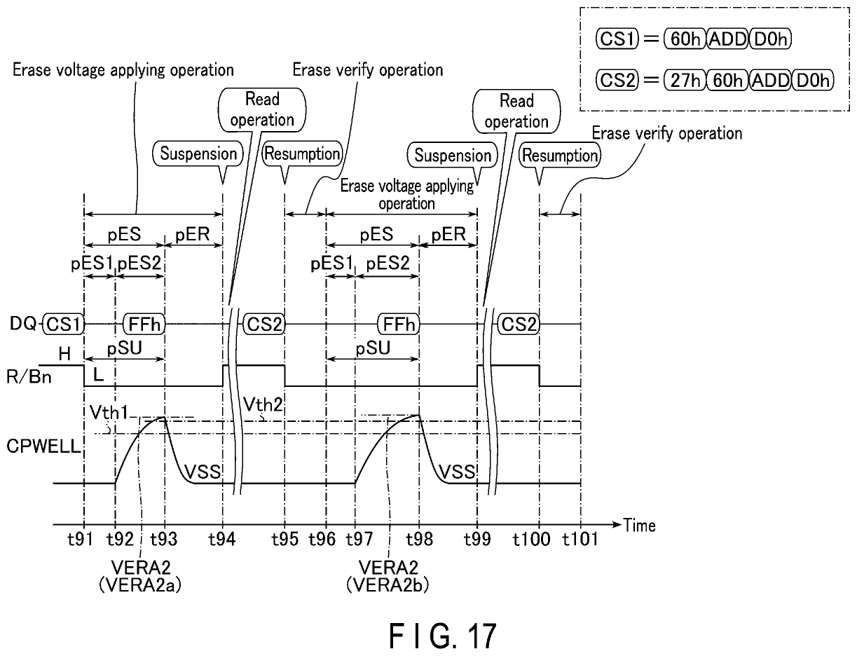

FIG. 17 is a timing chart illustrating an example of the erase operation of the NAND flash memory 30. FIG. 17 illustrates that a case where the command “FFh” is received during the boost period pSU in the period in one erase loop other than the verify skip period pVS and a situation in which the voltage VERA2 of the well line CPWELL at the time of receiving the command “FFh” is higher than the second threshold value Vth2 is repeated twice. Further, in FIG. 17, the interrupt processing is, for example, the read operation. Note that in FIG. 17, the voltages of the source line CELSRC, the bit line BL, the select gate lines SGD and SGS, and the word line WL are omitted. As illustrated in FIG. 7, waveforms of the source line CELSRC and the bit line BL are substantially the same as that of the well line CPWELL.

As illustrated in FIG. 17, in a case where the sequencer 36 receives the command set CS1 from the memory controller 10 at time t91, the ready/busy signal RBn is transitioned from the H level to the L level. The sequencer 36 starts the erase voltage applying operation based on the received command set CS1.

An operation in a period from time t91 to time t92 is similar to the operation in the period from time t41 to time t42 in FIG. 13.

At time t92, the driver module 37 applies the voltage VERA to the well line CPWELL and the source line CELSRC. The sense amplifier module 39 applies the voltage VERA to the bit line BL. By the application of the voltage VERA, the voltages of the well line CPWELL, the source line CELSRC, and the bit line BL increase.

Here, for example, it is assumed that the memory controller 10 receives the request for interrupt processing of the read operation from the host 2 in a period from time t92 to time t93. In this case, the memory controller 10 transmits, for example, the command “FFh” to the NAND flash memory 30 as the signal DQ.

Upon receiving the command “FFh” from the memory controller 10 at time t93 (during the boost period pSU), the sequencer 36 ends the processing of the setup period pES and starts the processing of the recovery period pER. The voltage VERA2 (voltage VERA2a) of the well line CPWELL at this time is higher than the second threshold value Vth2.

At time t93, the driver module 37 applies the voltage VSS to the well line CPWELL and the source line CELSRC. The sense amplifier module 39 applies the voltage VSS to the bit line BL. By the application of the voltage VSS, the voltages of the well line CPWELL, the source line CELSRC, and the bit line BL decrease.

In a case where the voltages of the well line CPWELL, the source line CELSRC, the bit line BL, the select gate lines SGD and SGS, and the word line WL are stepped down to the voltage VSS at time t94, the ready/busy signal RBn is transitioned from the L level to the H level. Thus, the erase voltage applying operation is suspended, and the interrupt processing is performed.

After the interrupt processing is performed, the memory controller 10 transmits, for example, the command set CS2 to the NAND flash memory 30 as the signal DQ in a period until time t95.

In a case where the sequencer 36 receives the command set CS2 from the memory controller 10 at time t95, the ready/busy signal RBn is transitioned from the H level to the L level. The sequencer 36 resumes the erase operation based on the received command set CS2. In a case where the voltage VERA2 of the well line CPWELL at the time of receiving the command “FFh” is higher than the second threshold value Vth2, the sequencer 36 performs the erase verify operation as the operation at the time of resumption.

During a period from time t95 to time t96, the sequencer 36 performs the erase verify operation.

An operation in a period from time t96 to time t101 is similar to the operation in the period from time t91 to time t96.

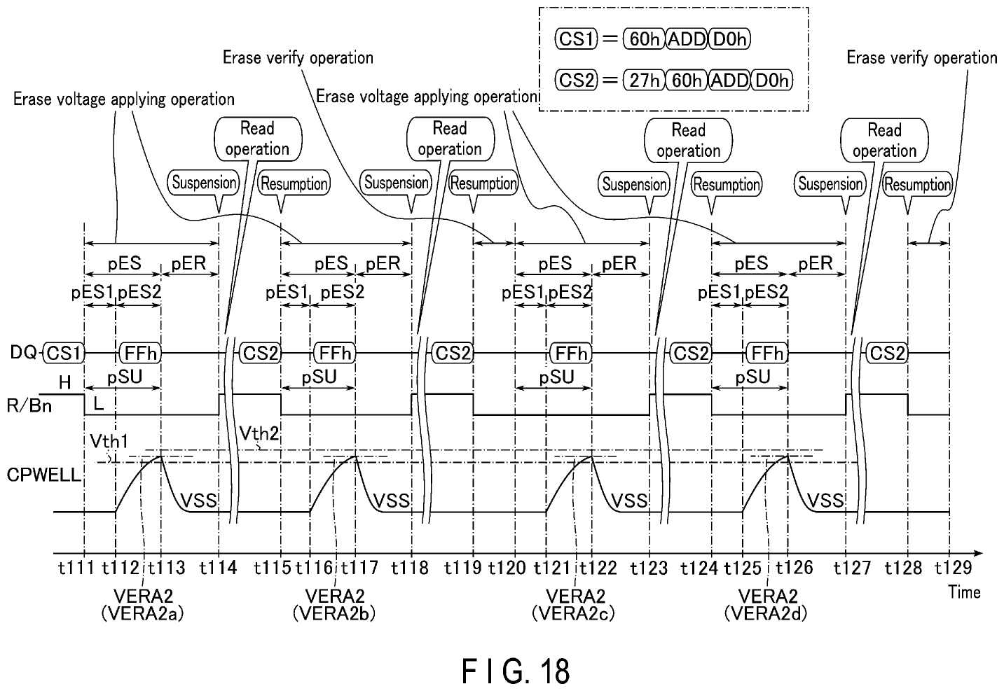

FIG. 18 is a timing chart illustrating another example of the erase operation of the NAND flash memory 30. FIG. 18 illustrates that a case where the command “FFh” is received during the boost period pSU in the period in one erase loop other than the verify skip period pVS and a situation in which the voltage VERA2 of the well line CPWELL at the time of receiving the command “FFh” is higher than the first threshold value Vth1 and equal to or lower than the second threshold value Vth2 is repeated four times. Further, in FIG. 18, the interrupt processing is, for example, the read operation. Note that in FIG. 18, the voltages of the source line CELSRC, the bit line BL, the select gate lines SGD and SGS, and the word line WL are omitted. As illustrated in FIG. 7, waveforms of the source line CELSRC and the bit line BL are substantially the same as that of the well line CPWELL.

As illustrated in FIG. 18, in a case where the sequencer 36 receives the command set CS1 from the memory controller 10 at time till, the ready/busy signal RBn is transitioned from the H level to the L level. In a case where the ready/busy signal RBn is transitioned to the L level, the sequencer 36 starts the erase voltage applying operation based on the received command set CS1.

An operation in a period from time till to time t112 is similar to the operation in the period from time t91 to time t92 in FIG. 17.

At time t112, the driver module 37 applies the voltage VERA to the well line CPWELL and the source line CELSRC. The sense amplifier module 39 applies the voltage VERA to the bit line BL. By the application of the voltage VERA, the voltages of the well line CPWELL, the source line CELSRC, and the bit line BL increase.

Here, for example, it is assumed that the memory controller 10 receives the request for interrupt processing of the read operation from the host 2 in a period from time t112 to time t113. In this case, the memory controller 10 transmits, for example, the command “FFh” to the NAND flash memory 30 as the signal DQ.

Upon receiving the command “FFh” from the memory controller 10 at time t113 (during the boost period pSU), the sequencer 36 ends the processing of the erase execution period pEW and starts the processing of the recovery period pER. The voltage VERA2 (VERA2a) of the well line CPWELL at this time is higher than the first threshold value Vth1 and equal to or lower than the second threshold value Vth2.

At time t113, the driver module 37 applies the voltage VSS to the well line CPWELL and the source line CELSRC. The sense amplifier module 39 applies the voltage VSS to the bit line BL. By the application of the voltage VSS, the voltages of the well line CPWELL, the source line CELSRC, and the bit line BL decrease.

In a case where the voltages of the well line CPWELL, the source line CELSRC, the bit line BL, the select gate lines SGD and SGS, and the word line WL are stepped down to the voltage VSS at time t114, the ready/busy signal RBn is transitioned from the L level to the H level. Thus, the erase voltage applying operation is suspended, and the interrupt processing is performed.

After the interrupt processing is performed, the memory controller 10 transmits, for example, the command set CS2 to the NAND flash memory 30 as the signal DQ in a period until time t115.

In a case where the sequencer 36 receives the command set CS2 from the memory controller 10 at time t115, the ready/busy signal RBn is transitioned from the H level to the L level. The sequencer 36 resumes the erase operation based on the received command set CS2. In a case where the voltage VERA2 (voltage VERA2a) of the well line CPWELL at the time of receiving the command “FFh” is higher than the first threshold value Vth1 and equal to or lower than the second threshold value Vth2, and the erase operation has not been continuously suspended twice at the voltage VERA2 satisfying “first threshold value Vth1<voltage VERA2≤second threshold value Vth2” in one erase loop, the sequencer 36 performs the erase voltage applying operation as the operation at the time of resumption.

An operation in a period from time t115 to time t119 is similar to an operation in a period from time till to time t115.

In a case where the sequencer 36 receives the command set CS2 from the memory controller 10 at time t119, the ready/busy signal RBn is transitioned from the H level to the L level. The sequencer 36 resumes the erase operation based on the received command set CS2. In a case where the voltage VERA2 (voltage VERA2b) of the well line CPWELL at the time of receiving the command “FFh” is higher than the first threshold value Vth1 and equal to or lower than the second threshold value Vth2, the erase operation has been continuously suspended twice at the voltage VERA2 satisfying “first threshold value Vth1<voltage VERA2≤second threshold value Vth2” in one erase loop, and the erase verify operation has not been performed after the previous suspension, the sequencer 36 performs the erase verify operation as the operation at the time of resumption.

During a period from time t119 to time t120, the sequencer 36 performs the erase verify operation.

An operation in a period from time t120 to time t124 is similar to the operation in the period from time till to time t115.

In a case where the sequencer 36 receives the command set CS2 from the memory controller 10 at time t124, the ready/busy signal RBn is transitioned from the H level to the L level. The sequencer 36 resumes the erase operation based on the received command set CS2. In a case where the voltage VERA2 (voltage VERA2c) of the well line CPWELL at the time of receiving the command “FFh” is higher than the first threshold value Vth1 and equal to or lower than the second threshold value Vth2, the erase operation has been continuously suspended twice at the voltage VERA2 satisfying “first threshold value Vth1<voltage VERA2≤second threshold value Vth2” in one erase loop, and the erase verify operation has been performed after the previous suspension, the sequencer 36 performs the erase voltage applying operation as the operation at the time of resumption.

An operation in a period from time t124 to time t128 is similar to the operation in the period from time till to time t115.

In a case where the sequencer 36 receives the command set CS2 from the memory controller 10 at time t128, the ready/busy signal RBn is transitioned from the H level to the L level. The sequencer 36 resumes the erase operation based on the received command set CS2. In a case where the voltage VERA2 (voltage VERA2d) of the well line CPWELL at the time of receiving the command “FFh” is higher than the first threshold value Vth1 and equal to or lower than the second threshold value Vth2, the erase operation has been continuously suspended twice at the voltage VERA2 satisfying “first threshold value Vth1<voltage VERA2≤second threshold value Vth2” in one erase loop, and the erase verify operation has not been performed after the previous suspension, the sequencer 36 performs the erase verify operation as the operation at the time of resumption.

During a period from time t128 to time t129, the sequencer 36 performs the erase verify operation.

### 3.2 Effects According to the Present Embodiment

According to the third embodiment, the same effects as those of the first embodiment are obtained.

Further, in the present embodiment, in a case where the voltage VERA2 is higher than the second threshold value Vth2, the sequencer 36 performs the erase verify operation as the operation at the time of resumption. In a case where the voltage VERA2 is equal to or lower than the first threshold value Vth1 (a voltage lower than the second threshold value Vth2), the sequencer 36 performs the erase voltage applying operation as the operation at the time of resumption. In a case where the voltage VERA2 is higher than the first threshold value Vth1 and equal to or lower than the second threshold value Vth2, the following operation is performed. In a case where the erase operation has not been continuously suspended twice at the voltage VERA2 satisfying “first threshold value Vth1<voltage VERA2≤second threshold value Vth2” in one erase loop, the sequencer 36 performs the erase voltage applying operation at the time of resumption. In a case where the erase operation has been continuously suspended twice at the voltage VERA2 satisfying “first threshold value Vth1<voltage VERA2≤second threshold value Vth2” in one erase loop and the erase verify operation has been performed from the previous suspension to the current suspension, the sequencer 36 performs the erase voltage applying operation at the time of the current resumption. In a case where the erase operation has been continuously suspended twice at the voltage VERA2 satisfying “first threshold value Vth1<voltage VERA2≤second threshold value Vth2” in one erase loop and the erase verify operation has not been performed from the previous suspension to the current suspension, the sequencer 36 performs the erase verify operation at the time of the current resumption. Therefore, according to the present embodiment, it is possible to suppress excessive decrease of the threshold voltage of the memory cell MC while suppressing the number of erase verify operations.

### 3.3 First Modification

The semiconductor memory device according to a first modification of the third embodiment will be described. In the semiconductor memory device according to the first modification of the third embodiment, the erase operation is different from that of the third embodiment. In the following description, differences from the third embodiment will be mainly described.

### 3.3.1 Erase Operation (in a Case where Instruction of Suspension is Received)

Details of the erase operation in a case where the sequencer 36 receives the instruction of suspension during the erase operation will be described.

### (Flowchart)

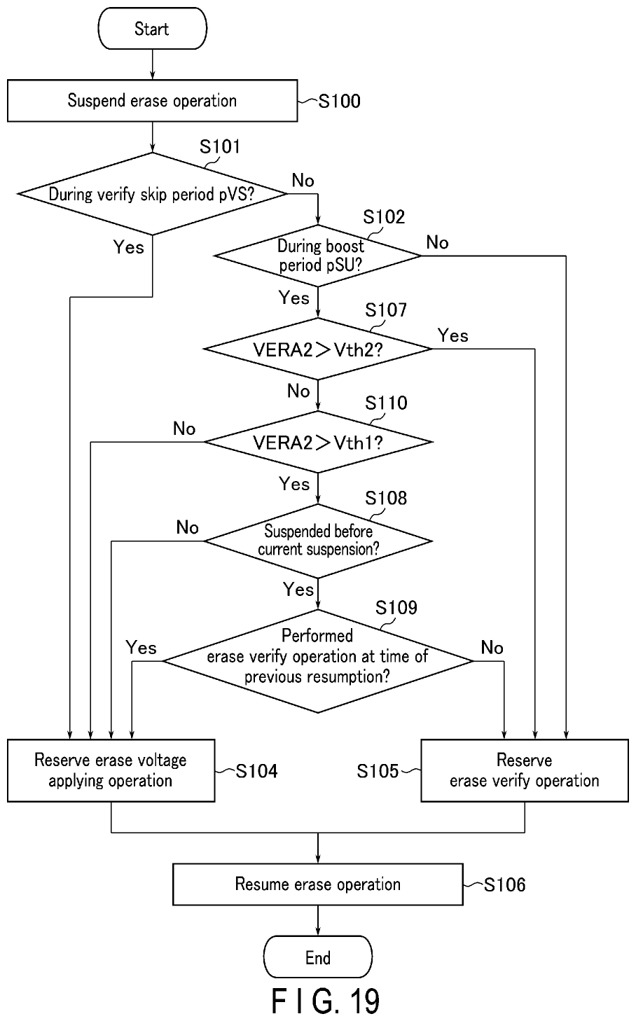

FIG. 19 is a flowchart illustrating an example of the erase operation of the NAND flash memory 30. FIG. 19 illustrates a case where the sequencer 36 receives the command “FFh” during the erase operation as the example of the erase operation. In FIG. 19, steps S111 and S112 in FIG. 16 illustrated in the third embodiment are replaced with steps S108 and S109 in FIG. 12 illustrated in the second embodiment.

In a case where the voltage VERA2 is equal to or lower than the second threshold value Vth2 (No in S107), the sequencer 36 determines whether the voltage VERA2 is higher than the first threshold value Vth1 (S110).

In a case where the voltage VERA2 is higher than the first threshold value Vth1 (Yes in S110), the sequencer 36 determines whether the erase operation has been suspended at the voltage VERA2 satisfying “first threshold value Vth1<voltage VERA2≤second threshold value Vth2” before the current suspension in one erase loop (S108). The determination method is, for example, similar to that of the second embodiment.

In one erase loop, in a case where the erase operation has not been suspended at the voltage VERA2 satisfying “first threshold value Vth1<voltage VERA2≤second threshold value Vth2” before the current suspension (No in S108), the sequencer 36 reserves the erase voltage applying operation as the operation at the time of the current resumption (at the time of resuming the erase operation suspended by the first suspension processing) (S104).

On the other hand, in one erase loop, in a case where the erase operation has been suspended at the voltage VERA2 satisfying “first threshold value Vth1<voltage VERA2≤second threshold value Vth2” before the current suspension (Yes in S108), the sequencer 36 determines whether the erase verify operation has been performed at the time of the previous resumption (at the time of resuming the erase operation suspended by the second suspension processing) (S109).

In a case where the erase verify operation has been performed at the time of the previous resumption (Yes in S109), the sequencer 36 reserves the erase voltage applying operation as the operation at the time of the current resumption (S104).

On the other hand, in a case where the erase verify operation has not been performed at the time of the previous resumption (No in S109), the sequencer 36 reserves the erase verify operation as the operation at the time of the current resumption (S105). In other words, in the period in one erase loop other than the verify skip period pVS, in a case where a situation in which the voltage VERA2 of the well line CPWELL when the sequencer 36 receives the command “FFh” during the boost period pSU is “first threshold value Vth1<voltage VERA2≤second threshold value Vth2” is repeated twice, and the erase verify operation has not been performed, the sequencer 36 reserves the erase verify operation as the operation at the time of the current resumption.

As described above, the sequencer 36 performs the erase voltage applying operation or the erase verify operation at the time of resuming the suspended erase operation based on the value of the voltage VERA2 of the well line CPWELL at the time of receiving the command “FFh” and the number of suspensions at the voltage VERA2 satisfying “first threshold value Vth1<voltage VERA2≤second threshold value Vth2” in one erase loop. The command “FFh” is not invalidated.

In a case where the voltage VERA2 is higher than the second threshold value Vth2, there is a relatively high possibility that the threshold voltage of the memory cell MC decreases lower than the target voltage. Therefore, in this case, the sequencer 36 performs the erase verify operation at the time of resumption.

In a case where the voltage VERA2 is higher than the first threshold value Vth1 and equal to or lower than the second threshold value Vth2, the threshold voltage of the memory cell MC is less likely to decrease lower than the target voltage as compared with the case where the voltage VERA2 is higher than the second threshold value Vth2. However, in a case where the erase operation has been continuously suspended twice at the voltage VERA2 satisfying “first threshold value Vth1<voltage VERA2≤second threshold value Vth2” in one erase loop, and the erase verify operation has not been performed from the previous suspension to the current suspension, even if the threshold voltage of the memory cell MC decreases lower than the target voltage in the erase voltage applying operation at the time of resumption after the previous suspension, this may not be detected. In this case, the threshold voltage of the memory cell MC may excessively decrease. Therefore, in a case where the erase operation has not been continuously suspended twice at the voltage VERA2 satisfying “first threshold value Vth1<voltage VERA2≤second threshold value Vth2” in one erase loop, the sequencer 36 performs the erase voltage applying operation at the time of resumption. In a case where the erase operation has been continuously suspended twice at the voltage VERA2 satisfying “first threshold value Vth1<voltage VERA2≤second threshold value Vth2” in one erase loop and the erase verify operation has been performed at the time of resumption after the previous suspension, the sequencer 36 performs the erase voltage applying operation at the time of the current resumption. In a case where the erase operation has been continuously suspended twice at the voltage VERA2 satisfying “first threshold value Vth1<voltage VERA2≤second threshold value Vth2” in one erase loop and the erase verify operation has not been performed at the time of resumption after the previous suspension, the sequencer 36 performs the erase verify operation at the time of the current resumption.

In a case where the voltage VERA2 is equal to or lower than the first threshold value Vth1, there is a relatively high possibility that the threshold voltage of the memory cell MC does not decrease. Therefore, in this case, the sequencer 36 performs the erase voltage applying operation at the time of resumption.

Note that in a case where the voltage VERA2 of the well line CPWELL is higher than the first threshold value Vth1 and equal to or lower than the second threshold value Vth2, and the second suspension processing of suspending the erase operation has been performed p times (p is an integer of 2 or more) when it is before the first suspension processing and the voltage VERA2 is higher than the first threshold value Vth1 and equal to or lower than the second threshold value Vth2 in one erase loop, the erase voltage applying operation or the erase verify operation may be performed at the time of resuming the erase operation suspended by the first suspension processing. In a case where the second suspension processing has not been performed p times when it is before the first suspension processing and the voltage VERA2 is higher than the first threshold value Vth1 and equal to or lower than the second threshold value Vth2 in one erase loop, the erase voltage applying operation may be performed at the time of resuming the erase operation suspended by the first suspension processing.

### (Timing Chart)

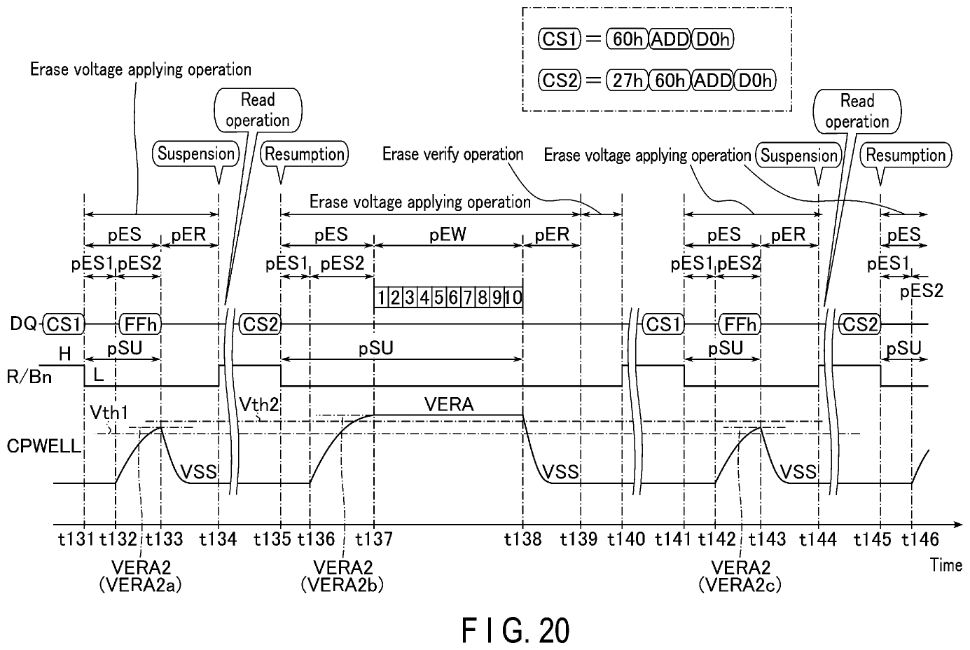

FIG. 20 is a timing chart illustrating an example of the erase operation of the NAND flash memory 30. FIG. 20 illustrates a case where the command “FFh” is received during the boost period pSU in the period in one erase loop other than the verify skip period pVS and the voltage VERA2 of the well line CPWELL at the time of receiving the command “FFh” is higher than the first threshold value Vth1 and equal to or lower than the second threshold value Vth2. Further, in FIG. 20, the interrupt processing is, for example, the read operation. Note that in FIG. 20, the voltages of the source line CELSRC, the bit line BL, the select gate lines SGD and SGS, and the word line WL are omitted. As illustrated in FIG. 7, waveforms of the source line CELSRC and the bit line BL are substantially the same as that of the well line CPWELL.

As illustrated in FIG. 20, in a case where the sequencer 36 receives the command set CS1 from the memory controller 10 at time t131, the ready/busy signal RBn is transitioned from the H level to the L level. The sequencer 36 starts the erase voltage applying operation based on the received command set CS1.

An operation in a period from time t131 to time t135 is similar to the operation in the period from time till to time t115 in FIG. 18.

In a case where the sequencer 36 receives the command set CS2 from the memory controller 10 at time t135, the ready/busy signal RBn is transitioned from the H level to the L level. The sequencer 36 resumes the erase operation based on the received command set CS2. In a case where the voltage VERA2 (VERA2a) of the well line CPWELL at the time of receiving the command “FFh” is higher than the first threshold value Vth1 and equal to or lower than the second threshold value Vth2, and the erase operation has not been continuously suspended twice at the voltage VERA2 satisfying “first threshold value Vth1<voltage VERA2≤second threshold value Vth2” in one erase loop, the sequencer 36 performs the erase voltage applying operation as the operation at the time of resumption.

An operation in a period from time t135 to time t139 is similar to the operation in the period from time t45 to time t49 in FIG. 13.

During a period from time t139 to time t140, the sequencer 36 performs the erase verify operation. In a case where the erase verify operation ends, the ready/busy signal RBn is transitioned from the L level to the H level.

In a case where the sequencer 36 receives the command set CS1 from the memory controller 10 at time t141, the ready/busy signal RBn is transitioned from the H level to the L level. The sequencer 36 starts the erase voltage applying operation based on the received command set CS1.

An operation in a period from time t141 to time t145 is similar to the operation in the period from time t131 to time t135.

In a case where the sequencer 36 receives the command set CS2 from the memory controller 10 at time t145, the ready/busy signal RBn is transitioned from the H level to the L level. The sequencer 36 resumes the erase operation based on the received command set CS2. In a case where the voltage VERA2 (VERA2c) of the well line CPWELL at the time of receiving the command “FFh” is higher than the first threshold value Vth1 and equal to or lower than the second threshold value Vth2, and the erase operation has not been continuously suspended twice at the voltage VERA2 satisfying “first threshold value Vth1<voltage VERA2≤second threshold value Vth2” in one erase loop, the sequencer 36 performs the erase voltage applying operation as the operation at the time of resumption.

### 3.3.2 Effects According to the Present Modification

According to the present modification, the same effects as those of the first embodiment are obtained.

Further, in the present modification, in a case where the voltage VERA2 is higher than the second threshold value Vth2, the sequencer 36 performs the erase verify operation as the operation at the time of resumption. In a case where the voltage VERA2 is equal to or lower than the first threshold value Vth1 (a voltage lower than the second threshold value Vth2), the sequencer 36 performs the erase voltage applying operation as the operation at the time of resumption. In a case where the voltage VERA2 is higher than the first threshold value Vth1 and equal to or lower than the second threshold value Vth2, the sequencer 36 performs the erase voltage applying operation as the operation at the time of resumption. Even if the voltage VERA2 is higher than the first threshold value Vth1 and equal to or lower than the second threshold value Vth2, in the period in one erase loop other than the verify skip period pVS, in a case where a situation in which the voltage VERA2 is higher than the first threshold value Vth1 and equal to or lower than the second threshold value Vth2 is repeated twice, the sequencer 36 performs the erase verify operation as the operation at the time of resumption. Therefore, according to the present modification, it is possible to suppress excessive decrease of the threshold voltage of the memory cell MC while suppressing the number of erase verify operations.

### 3.4 Second Modification

The semiconductor memory device according to a second modification of the third embodiment will be described. In the semiconductor memory device according to the second modification of the third embodiment, the erase operation is different from that of the third embodiment. In the following description, differences from the third embodiment will be mainly described.

### 3.4.1 Erase Operation (in a Case where Instruction of Suspension is Received)

Details of the erase operation in a case where the sequencer 36 receives the instruction of suspension during the erase operation will be described.

### (Flowchart)

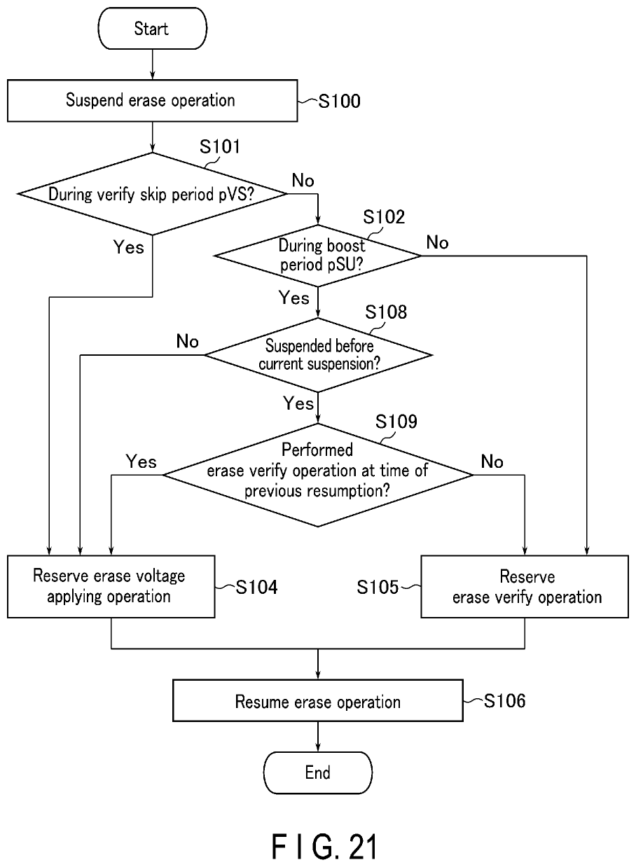

FIG. 21 is a flowchart illustrating an example of the erase operation of the NAND flash memory 30. FIG. 21 illustrates a case where the sequencer 36 receives the command “FFh” during the erase operation as the example of the erase operation. In FIG. 21, steps S107 and S110 in FIG. 16 illustrated in the third embodiment are eliminated, and steps S111 and S112 in FIG. 16 are replaced with steps S108 and S109 in FIG. 12 illustrated in the second embodiment.

In a case where the boost period pSU is in progress (Yes in S102), the sequencer 36 determines whether the erase operation has been suspended before the current suspension (the first suspension processing) in one erase loop (S108). For example, the sequencer 36 determines whether the resumption operation information Iar is stored in the latch circuit 41. In a case where the resumption operation information Iar is stored, the sequencer 36 determines that the suspension (the second suspension processing) of the erase operation has been performed before the current suspension (the first suspension processing) in one erase loop. In a case where the resumption operation information Iar is not stored, the sequencer 36 determines that the suspension (the second suspension processing) of the erase operation has not been performed before the current suspension (the first suspension processing) in one erase loop.

In one erase loop, in a case where the erase operation has not been suspended before the current suspension (No in S108), the sequencer 36 reserves the erase voltage applying operation as an operation at the time of the current resumption (at the time of resuming the erase operation suspended by the first suspension processing) (S104). For example, the sequencer 36 stores as the resumption operation information Iar the “erase voltage applying operation” meaning that the operation at the time of resumption is the erase voltage applying operation, the voltage (voltage VERA2) of the well line CPWELL at the time of suspension, the suspension time, the boost start voltage (the set value of voltage VERA), and the boost method in the latch circuit 41. In a case where the interrupt processing ends, the sequencer 36 resumes the erase operation (S106). That is, the sequencer 36 performs the reserved erase voltage applying operation.

On the other hand, in one erase loop, in a case where the erase operation has been suspended before the current suspension (Yes in S108), the sequencer 36 determines whether the erase verify operation has been performed at the time of the previous resumption (at the time of resuming the erase operation suspended by the second suspension processing) (S109). For example, the sequencer 36 acquires the resumption operation information Iar from the latch circuit 41, and determines whether the erase verify operation has been performed at the time of the previous resumption based on the acquired resumption operation information Iar.

In a case where the erase verify operation has been performed at the time of the previous resumption (Yes in S109), the sequencer 36 reserves the erase voltage applying operation as the operation at the time of the current resumption (S104). In a case where the interrupt processing ends, the sequencer 36 resumes the erase operation (S106). That is, the sequencer 36 performs the reserved erase voltage applying operation.

On the other hand, in a case where the erase verify operation has not been performed at the time of the previous resumption (No in S109), the sequencer 36 reserves the erase verify operation as the operation at the time of the current resumption (S105). In other words, in the period in one erase loop other than the verify skip period pVS, in the case where a situation in which the sequencer 36 receives the command “FFh” during the boost period pSU is repeated twice, the sequencer 36 reserves the erase verify operation as the operation at the time of the current resumption. For example, the sequencer 36 stores the “erase verify operation” meaning that the operation at the time of resumption is the erase verify operation in the latch circuit 41 as the resumption operation information Iar. In a case where the interrupt processing ends, the sequencer 36 resumes the erase operation (S106). That is, the sequencer 36 performs the reserved erase verify operation.

As described above, the sequencer 36 performs the erase voltage applying operation or the erase verify operation at the time of resuming the suspended erase operation based on the number of suspensions in one erase loop. The command “FFh” is not invalidated.

In a case where the erase operation has been continuously suspended twice in one erase loop, and the erase verify operation is not performed at the time of resumption after the previous suspension, even if the threshold voltage of the memory cell MC decreases lower than the target voltage in the erase voltage applying operation at the time of resumption after the previous suspension, this may not be detected. In this case, the threshold voltage of the memory cell MC may excessively decrease. Therefore, in a case where the erase operation has not been continuously suspended twice in one erase loop, the sequencer 36 performs the erase voltage applying operation at the time of resumption. In a case where the erase operation has been continuously suspended twice in one erase loop and the erase verify operation has been performed at the time of resumption after the previous suspension, the sequencer 36 performs the erase voltage applying operation at the time of the current resumption. In a case where the erase operation has been continuously suspended twice in one erase loop and the erase verify operation has not been performed at the time of resumption after the previous suspension, the sequencer 36 performs the erase verify operation at the time of the current resumption.

Note that in a case where the second suspension processing of suspending the erase operation has been performed p times (p is an integer of 2 or more) before the first suspension processing, the erase voltage applying operation or the erase verify operation may be performed at the time of resuming the erase operation suspended by the first suspension processing. In a case where the second suspension processing has not been performed p times before the first suspension processing, the erase voltage applying operation may be performed at the time of resuming the erase operation suspended by the first suspension processing.

### (Timing Chart)

A timing chart illustrating an example of the erase operation of the NAND flash memory 30 according to the present modification is similar to FIGS. 13 to 15 illustrated in the second embodiment. In the present modification, in the period in one erase loop other than the verify skip period pVS, in the case where a situation in which the sequencer 36 receives the command “FFh” during the boost period pSU is repeated twice, the sequencer 36 performs the erase verify operation as the operation at the time of resumption. Note that in the period in one erase loop other than the verify skip period pVS, in the case where a situation in which the sequencer 36 receives the command “FFh” during the boost period pSU is repeated three or more times, the erase verify operation may be performed as the operation at the time of resumption.

### 3.4.2 Effects According to the Present Modification

According to the present modification, the same effects as those of the first embodiment are obtained.

Further, in the present modification, in the period in one erase loop other than the verify skip period pVS, in the case where a situation in which the sequencer 36 receives the command “FFh” during the boost period pSU is repeated twice, the sequencer 36 performs the erase verify operation as the operation at the time of resumption. Therefore, according to the present embodiment, it is possible to suppress excessive decrease of the threshold voltage of the memory cell MC.

### 4. Modifications and the Like

As described above, a semiconductor memory device according to an embodiment includes a memory cell (MC) including a transistor, an interconnect (CPWELL), and a first circuit (36). The first circuit (36) performs an erase operation including an erase voltage applying operation of applying an erase voltage (VERA) between a gate of the transistor and a channel of the transistor via the interconnect (CPWELL), and an erase verify operation of determining a threshold voltage of the memory cell (MC). The first circuit (36) performs a first suspension processing of suspending the erase operation upon receiving a first command (FFh) during the erase operation. The first circuit (36) performs the erase voltage applying operation or the erase verify operation at the time of resuming the erase operation suspended by the first suspension processing, based on a voltage value (VERA1/VERA2) of the interconnect (CPWELL) at the time of receiving the first command (FFh).

Note that the embodiments are not limited to the above-described embodiments, and various modifications can be made.

In addition, in the flowcharts described in the above embodiments, the order of the processing can be changed as much as possible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell including a transistor;
an interconnect; and
a first circuit configured to perform an erase operation including an erase voltage applying operation of applying an erase voltage between a gate of the transistor and a channel of the transistor via the interconnect and an erase verify operation of determining a threshold voltage of the memory cell, wherein
the first circuit performs a first suspension processing of suspending the erase operation upon receiving a first command during the erase operation, and
the first circuit performs the erase voltage applying operation or the erase verify operation at the time of resuming the erase operation suspended by the first suspension processing, based on a voltage value of the interconnect at the time of receiving the first command.

2. The device according to claim 1, wherein a timing at which the first command is received is during the erase voltage applying operation.

3. The device according to claim 1, wherein
in a case where the voltage value of the interconnect is higher than a first threshold value, the first circuit performs the erase verify operation at the time of resuming the erase operation suspended by the first suspension processing, and
in a case where the voltage value of the interconnect is equal to or lower than the first threshold value, the first circuit performs the erase voltage applying operation at the time of resuming the erase operation suspended by the first suspension processing.

4. The device according to claim 1, wherein
in a case where the voltage value of the interconnect is higher than a second threshold value, the first circuit performs the erase verify operation at the time of resuming the erase operation suspended by the first suspension processing,
in a case where the voltage value of the interconnect is equal to or lower than the second threshold value, and a second suspension processing of suspending the erase operation has been performed when it is before the first suspension processing and the voltage value of the interconnect is equal to or lower than the second threshold value, the first circuit performs the erase voltage applying operation or the erase verify operation at the time of resuming the erase operation suspended by the first suspension processing, and
in a case where the voltage value of the interconnect is equal to or lower than the second threshold value, and the second suspension processing has not been performed when it is before the first suspension processing and the voltage value of the interconnect is equal to or lower than the second threshold value, the first circuit performs the erase voltage applying operation at the time of resuming the erase operation suspended by the first suspension processing.

5. The device according to claim 4, wherein
in a case where the voltage value of the interconnect is equal to or lower than the second threshold value, the second suspension processing has been performed when it is before the first suspension processing and the voltage value of the interconnect is equal to or lower than the second threshold value, and the erase verify operation has been performed at the time of resuming the erase operation suspended by the second suspension processing, the first circuit performs the erase voltage applying operation at the time of resuming the erase operation suspended by the first suspension processing, and
in a case where the voltage value of the interconnect is equal to or lower than the second threshold value, the second suspension processing has been performed when it is before the first suspension processing and the voltage value of the interconnect is equal to or lower than the second threshold value, and the erase verify operation has not been performed at the time of resuming the erase operation suspended by the second suspension processing, the first circuit performs the erase verify operation at the time of resuming the erase operation suspended by the first suspension processing.

6. The device according to claim 1, wherein
in a case where the voltage value of the interconnect is equal to or lower than a first threshold value, the first circuit performs the erase voltage applying operation at the time of resuming the erase operation suspended by the first suspension processing,
in a case where the voltage value of the interconnect is higher than the first threshold value and equal to or lower than a second threshold value, and a second suspension processing of suspending the erase operation has been performed when it is before the first suspension processing and the voltage value of the interconnect is higher than the first threshold value and equal to or lower than the second threshold value, the first circuit performs the erase voltage applying operation or the erase verify operation at the time of resuming the erase operation suspended by the first suspension processing,
in a case where the voltage value of the interconnect is higher than the first threshold value and equal to or lower than a second threshold value, and the second suspension processing has not been performed when it is before the first suspension processing and the voltage value of the interconnect is higher than the first threshold value and equal to or lower than the second threshold value, the first circuit performs the erase voltage applying operation at the time of resuming the erase operation suspended by the first suspension processing, and
in a case where the voltage value of the interconnect is higher than the second threshold value, the first circuit performs the erase verify operation at the time of resuming the erase operation suspended by the first suspension processing.

7. The device according to claim 6, wherein
in a case where the voltage value of the interconnect is higher than the first threshold value and equal to or lower than the second threshold value, the second suspension processing has been performed when it is before the first suspension processing and the voltage value of the interconnect is higher than the first threshold value and equal to or lower than the second threshold value, and the erase verify operation has been performed from the second suspension processing to the first suspension processing, the first circuit performs the erase voltage applying operation at the time of resuming the erase operation suspended by the first suspension processing, and
in a case where the voltage value of the interconnect is higher than the first threshold value and equal to or lower than the second threshold value, the second suspension processing has been performed when it is before the first suspension processing and the voltage value of the interconnect is higher than the first threshold value and equal to or lower than the second threshold value, and the erase verify operation has not been performed from the second suspension processing to the first suspension processing, the first circuit performs the erase verify operation at the time of resuming the erase operation suspended by the first suspension processing.

8. The device according to claim 6, wherein
in a case where the voltage value of the interconnect is higher than the first threshold value and equal to or lower than the second threshold value, the second suspension processing has been performed when it is before the first suspension processing and the voltage value of the interconnect is higher than the first threshold value and equal to or lower than the second threshold value, and the erase verify operation has been performed at the time of resuming the erase operation suspended by the second suspension processing, the first circuit performs the erase voltage applying operation at the time of resuming the erase operation suspended by the first suspension processing, and
in a case where the voltage value of the interconnect is higher than the first threshold value and equal to or lower than the second threshold value, the second suspension processing has been performed when it is before the first suspension processing and the voltage value of the interconnect is higher than the first threshold value and equal to or lower than the second threshold value, and the erase verify operation has not been performed at the time of resuming the erase operation suspended by the second suspension processing, the first circuit performs the erase verify operation at the time of resuming the erase operation suspended by the first suspension processing.

9. A semiconductor memory device comprising:
a memory cell including a transistor;
an interconnect; and
a first circuit configured to perform an erase operation including an erase voltage applying operation of applying an erase voltage between a gate of the transistor and a channel of the transistor via the interconnect and an erase verify operation of determining a threshold voltage of the memory cell, wherein
the first circuit performs a first suspension processing of suspending the erase operation upon receiving a first command during the erase operation,
in a case where a second suspension processing of suspending the erase operation has been performed before the first suspension processing, the first circuit performs the erase voltage applying operation or the erase verify operation at the time of resuming the erase operation suspended by the first suspension processing, and
in a case where the second suspension processing has not been performed before the first suspension processing, the first circuit performs the erase voltage applying operation at the time of resuming the erase operation suspended by the first suspension processing.

10. The device according to claim 9, wherein
in a case where the second suspension processing has been performed before the first suspension processing and the erase verify operation has been performed at the time of resuming the erase operation suspended by the second suspension processing, the first circuit performs the erase voltage applying operation at the time of resuming the erase operation suspended by the first suspension processing, and
in a case where the second suspension processing has been performed before the first suspension processing and the erase verify operation has not been performed at the time of resuming the erase operation suspended by the second suspension processing, the first circuit performs the erase verify operation at the time of resuming the erase operation suspended by the first suspension processing.

11. The device according to claim 1, wherein
in a case where the voltage value of the interconnect is higher than a second threshold value, the first circuit performs the erase verify operation at the time of resuming the erase operation suspended by the first suspension processing,
in a case where the voltage value of the interconnect is equal to or lower than the second threshold value, a second suspension processing of suspending the erase operation has been performed n times (n is an integer of 2 or more) when it is before the first suspension processing and the voltage value of the interconnect is equal to or lower than the second threshold value, the first circuit performs the erase voltage applying operation or the erase verify operation at the time of resuming the erase operation suspended by the first suspension processing, and
in a case where the voltage value of the interconnect is equal to or lower than the second threshold value, the second suspension processing has not been performed n times when it is before the first suspension processing and the voltage value of the interconnect is equal to or lower than the second threshold value, the first circuit performs the erase voltage applying operation at the time of resuming the erase operation suspended by the first suspension processing.

12. The device according to claim 1, wherein
in a case where the voltage value of the interconnect is equal to or lower than a first threshold value, the first circuit performs the erase voltage applying operation at the time of resuming the erase operation suspended by the first suspension processing,
in a case where the voltage value of the interconnect is higher than the first threshold value and equal to or lower than a second threshold value, and a second suspension processing of suspending the erase operation has been performed n times (n is an integer of 2 or more) when it is before the first suspension processing and the voltage value of the interconnect is higher than the first threshold value and equal to or lower than the second threshold value, the first circuit performs the erase voltage applying operation or the erase verify operation at the time of resuming the erase operation suspended by the first suspension processing,
in a case where the voltage value of the interconnect is higher than the first threshold value and equal to or lower than a second threshold value, and the second suspension processing has not been performed n times when it is before the first suspension processing and the voltage value of the interconnect is higher than the first threshold value and equal to or lower than the second threshold value, the first circuit performs the erase voltage applying operation at the time of resuming the erase operation suspended by the first suspension processing, and
in a case where the voltage value of the interconnect is higher than the second threshold value, the first circuit performs the erase verify operation at the time of resuming the erase operation suspended by the first suspension processing.

13. The device according to claim 9, wherein
in a case where the second suspension processing of suspending the erase operation has been performed n times (n is an integer of 2 or more) before the first suspension processing, the first circuit performs the erase voltage applying operation or the erase verify operation at the time of resuming the erase operation suspended by the first suspension processing, and
in a case where the second suspension processing has not been performed n times before the first suspension processing, the first circuit performs the erase voltage applying operation at the time of resuming the erase operation suspended by the first suspension processing.

14. The device according to claim 1, wherein the first command is not invalidated.

15. The device according to claim 1, wherein
in a case where the erase operation is suspended in a first period during an erase execution period in which the erase voltage is applied in the erase voltage applying operation,
after the erase operation is resumed, in the erase voltage applying operation, the erase execution period is started from the first period.

16. The device according to claim 1, wherein the transistor is a memory cell transistor.

17. The device according to claim 1, wherein the semiconductor memory device is a NAND flash memory.
